(19) United States
(12) Patent Application Publication
(10) Pub. No.: US 2025/0172601 A1
(43) Pub. Date: May 29, 2025

(54) ELECTRIC FIELD GENERATING DEVICE, ELECTRIC FIELD GENERATING SYSTEM, ELECTRIC FIELD DETECTING DEVICE, AND ELECTRIC FIELD DETECTION ASSEMBLY

(71) Applicants: ENSICAEN, Caen (FR); UNIVERSITE DE CAEN NORMANDIE, Caen (FR); CENTRE NATIONAL DE LA RECHERCHE SCIENTIFIQUE (CNRS), Paris (FR)

(72) Inventors: Didier ROBBES, Ponts sur Seulles (FR); Matthieu ROBLIN, Mondeville (FR); Gilles ALLEGRE, Vire Normandie (FR); Sylvain LEBARGY, Hérouville Saint Clair (FR); Thomas PACARY, Caen (FR); Julien GASNIER, Valorbiquet (FR); Matthieu DENOUAL, Caen (FR); Olivier MARESCHAL, Alencon (FR)

(21) Appl. No.: 18/843,510

(22) PCT Filed: Mar. 4, 2022
(86) PCT No.: PCT/IB2022/000277

§ 371 Date: Sep. 3, 2024

(51) Int. Cl. G01R 29/12

(52) U.S. Cl. CPC G01R 29/12

(57) ABSTRACT

The invention relates in various aspects to an electric field generating device, an electric field detecting device, and an electric field detection assembly. In some illustrative embodiments of an aspect, the electric field generating device includes a charge accumulation body, a support body of conductive material, and a conductor element of a conductive material. The conductor element extends through the support body. The charge accumulation body has a shape according to a desired electric potential distribution having equipotential faces in correspondence with a desired shape and the conductor element is electrically insulated from the support body.

### FIELD OF THE INVENTION

The invention relates to an electric field generating device, an electric field generating system, an electric field detecting device, and an electric field detection assembly.

### STATE OF THE ART

Electric and magnetic fields are present in every aspect of the human living and working environment and in a wide frequency and intensity range. The evaluation of magnetic fields and electric fields with respect to their potential to harm man and machine is an important aspect of modem electromagnetic compatibility (EMC), which is the ability of electrical equipment and systems to function acceptably in their electromagnetic environment, by limiting the unintentional generation, propagation and reception of electromagnetic energy which may cause unwanted effects such as electromagnetic interference (EMI) or even physical damage in operational equipment.

While measuring magnetic fields has been known for a long time, when regarding a compass as a simple measuring device for detecting a direction of a magnetic field, measuring electric fields is not as common as magnetic field sensing. For example, to date several different techniques for measuring magnetic fields exist, such as Fluxgate-, Hall- and magnetoresistance sensors, SQUIDs and induction coils with different frequency and amplitude ranges. One reason may be that magnetic field sensors with induction coils are based on search coils in which a magnetic field to be measured induces a certain voltage. As search coils may be fabricated in a great range of sizes, such magnetic field sensor can be made from rather small for integration into handheld devices, up to larger devices which may be very sophisticated. In contrast, measuring electric fields is more complex than measuring magnetic fields because, when measuring an electric field, there are more possible perturbations that could deteriorate a measurement as opposed to measurements of the magnetic field. For example, already a person undertaking the measurement, often perturbs an electric field to be measured.

Besides the state of the art of electric field measuring means, calibration means are needed to follow conventional metrology rules. These means necessarily include those dedicated to produce a well-known and reproducible electric field, both in strength and direction, together with a well-controlled time behavior. The ancient art starts with the Van de Graff electrostatic generator, which already is a very efficient way to produce the reference field of the charged sphere, but it is electrostatic in nature. In the Van de Graff electrostatic generator, the charged sphere is supported by a dielectric body made of a solid material having a dielectric constant as close as possible to that of its environment (vacuum, air, or other dielectric material) in order to avoid field lines deformation in the vicinity of the support body.

Notwithstanding the difficulties in measuring electric fields, efforts are made to improve the current situation because an accurate measurement of the electric field is desirable in many instances. For example, small-scale and distortion-free measurement of electric fields is crucial for applications such as surveying atmospheric electrostatic fields, lightning research, and safeguarding areas close to high-voltage power lines. Currently, a variety of measurement systems exist, the most common of which are field mills, which work by picking up the differential voltage of the measurement electrodes while periodically shielding them with a grounded electrode. However, all current approaches are either bulky, suffer from a strong temperature dependency, or severely distort the electric field requiring a well-defined surrounding and complex calibration procedures.

As indicated above, one difficulty in measuring the electric field is that it appears impossible to avoid interference of an electric field to be measured by the measuring instrument. One reason is that dielectric bodies develop surface charges which usually lead to moderate distortions of an electric field under measurement, while large, electrically conducting bodies generate significant field distortions in their proximity. This problem becomes even more serious, if parts of a sensor have to be grounded or connected to large conductors in order to establish a reference potential.

Current measurement systems for static and low-frequency electric field can be divided into two general categories: direct electrical conversion comprising double probes of electrical potential as well as field mills and electro-optical systems. All these approaches suffer from drawbacks like limited lifetime or scaleablity. For example, field mill measurements turn out to be inherently error-prone and strongly depend on the immediate environment, whereas electro-optical systems rely on specific dielectrics and do not require grounded connections, thereby appearing superior in comparison with field mills. However, electro-optical electric field sensors suffer from an intrinsic temperature instability due to the pyroelectric effect and the thermal expansion of the material.

Document EP 2 230 523 A1 relates to a physical quantity measuring unit, in particular a scalar physical measuring unit providing the scalar quantity and its gradient, comprising: a sensing means comprising a first and a second sensactor, wherein the first sensactor is configured to provide a first output and comprises a first and second feedback input and the second sensactor is configured to provide a second output and comprises a third and fourth feedback input, a fully differential amplifier means comprising differential outputs and a common mode output, wherein the first and second output of the sensing means is connected to a first input and a second input of the fully differential amplifier means respectively, two feedback loops connecting the differential outputs of the fully differential amplifier means to the first and third feedback inputs with a signal sign inversion, and a third feedback loop connecting the common mode output of the fully differential amplifier means with the second and fourth feedback inputs of the sensing means.

Furthermore, documents U.S. Pat. No. 9,279,719 B2, US 2015/0137825 A1, and US 2016/0049885 A1 disclose means to produce and sense quasi static electric fields and extract images from them. According to these works, the quasi static field is produced using a rotating electric dipole coupled to a large planar equipotential electrode, in the vicinity of which a quasi-uniform electric field is obtained (uniformity obtained in the limit of the infinite spatial extension of the large plane). In front of this plane, a network of sensing planar electrodes may detect change in the field associated to a moving object in between the source plane and the sensor's plane. Also as discussed in Generazio, E. R., Electric Potential and Electric Field Imaging with Applications, Materials Evaluation, November 2015, pgs. 1479-1489, an apparatus for producing electric field images is known which has the following limitations and drawbacks, both on the field sourcing and the field sensing:
Very limited frequency range of the produced electric field, associated to a mechanical solution,
No possible control of the produced field direction,
No clear way to control the produced field strength,
Only a map of voltages in a plane is measured from the sensors network. Accordingly, the three components of the modified electric field in the vicinity of the scanned object exposed to the produced field in the imaging apparatus are not available.

Accordingly, it is desirable to provide an electric field detecting device and an electric field detection assembly which overcome the before mentioned problems. It is also desirable to provide an electric field generating device and an electric field generating system.

### BRIEF SUMMARY OF THE DISCLOSURE

The issues of the state of the art discussed above are solved in various aspects by an electric field generating device as defined in independent claim 1, an electric field generating system as defined in independent claim 26, an electric field detecting device as defined in independent claim 32, and an electric field detection assembly as defined in independent claim 40. Advantageous embodiments of the various aspects are defined in the respective dependent claims.

The inventor recognized that an electric field detecting device and an electric field detection assembly which overcomes the drawbacks of the prior art makes a field source with predetermined nearly ideal properties of a generated electric field necessary. As described in the previous section with regard to the prior art, measuring of electric fields is difficult because any electric field to be measured is perturbed by measurement equipment. The solution as proposed by the inventor provides a field source which is not or little affected by perturbations caused by the field generating equipment. This field source is calculable to provide an ideal background field with known properties.

In a first aspect of the present disclosure, an electric field generating device is provided. In illustrative embodiments herein, the electric field generating device comprises a charge accumulation body, a support body in mechanical connection with the charge accumulation body, and a conductor element extending through the support body and electrically contacting the support body. The charge accumulation body has a shape so as to at least approximate a desired electric field around the accumulation body. Herein, the conductor element is electrically insulated from the support body in the support body outside the charge accumulation body. Accordingly, an electric potential around the charge accumulation body may be provided by a shape of the charge accumulation body, equipotential faces of the electric potential at least approximating a desired shape determined by the desired electric field.

In accordance with a first illustrative embodiment of the first aspect, the support body may have a locally varying electrical resistance which is adapted to generate an electric field such that an electric field generated by the electric field generating device is substantially an electric field generated by the charge accumulation body charged with an electric charge. For example, the support body may be provided by a material suitable for 3D printing, molding or forming or milling process techniques, such as without limitation at least one of PolyLactic Acid (PLAc), expanded thermoplastic polyurethane (EPTU), an epoxy resin (e.g., 337H), polypropylene (PP), or polyethylene (PE) and polyoxymethylene (PMO), e.g., polyoxymethylene-copolymer (POMC). However, this is not limiting and the support body may be provided by any electrically conductive material, e.g., an electrical resistive material and/or a metal material. Accordingly, the electric field generated by the electric field generating device substantially corresponds to or approximates an electric field generated by the charge accumulation body when assuming that the charged charge accumulation body as such is located within a space volume without the support body located nearby. In this way, the electric field generating device allows to generate an electric field in approximation of or substantially corresponding to an ideal electric field as theoretically generated by the charge accumulation body when being charged without the presence of the support body and other interfering bodies deforming the ideal electric field in a simple manner.

In accordance with a second illustrative embodiment of the first aspect, the conductor element may be in electrical contact with the support body at a contact point, the contact point being located within the charge accumulation body. Accordingly, an approximation of the field generated by the charge accumulation body to a desired field shape is improved.

In accordance with a third illustrative embodiment of the first aspect, an outer surface of the support body may be substantially parallel to the desired electric field at the outer surface. That is, the outer surface of the support body is substantially perpendicular to equipotential faces of the desired electric potential associated with the desired electric field at the support body or, in other words, the outer surface of the support body may be shaped such that field lines of an electric field generated by the charge accumulation body substantially extend within the outer surface of the support body (herein, a field line is understood as representing a graphical visual aid for visualizing vector fields, consisting of a directed line which is tangent to a field vector of the generated electric field at each point along its length such that a diagram showing a representative set of neighboring field lines typically depicts a vector field as a field line diagram). The local varying electrical resistance may be adopted to decrease with increasing distance from the charge accumulation body. Accordingly, an advantageous shaping of the electric field close to the support body may be easily achieved and a perturbation to the electric field generated by the charge accumulation body as a desired field distribution may be at least attenuated, such as a deviation of the electric field generated by the electric field generating device from the desired field distribution due to the presence of the support body and the conductor element.

In accordance with a fourth illustrative embodiment of the first aspect, the support body may be a hollow sleeve body, preferably of a conical shape or a triangular prism shape. In providing the support body by means of a hollow sleeve body, an advantageous electric field may be generated by the electric field generating device. For example, a conical support body may easily provide a symmetrical support body and may allow to provide an advantageous distribution of the electrical resistance along the support body.

In some illustrative examples of the fourth embodiment of the first aspect, an outer surface of the support body outside the charge accumulation body, when being extended into the charge accumulation body, may have a peak at a centroid of the charge accumulation body in a side sectional view of the electric field generating device. Thereby, it is possible to guarantee a best adequacy between a given model for the electric field to be generated by the electric field generating device, e.g., an electric field to be generated being an electric field of an ideal electrically charged sphere, and a proposed realization.

In a particular illustrative example, the support body may have an outer surface outside of the charge accumulation body, the outer surface being of a conical shape such that, when extending the outer surface towards the charge accumulation body into the charge accumulation body, it may have a peak at a centroid of the charge accumulation body.

In accordance with some illustrative examples of the fourth illustrative embodiment of the first aspect, the charge accumulation body may be an ellipsoidal body, preferably spherical body, or a cylindrical body. Accordingly, the desired electric field having a field configuration corresponding to the shape of the charge accumulation body, may be easily provided.

In a first illustrative example herein, where the charge accumulation body has the shape of a sphere, the electric field generated by the charge accumulation body may substantially have a 1/r² dependency of the electric field strength on a distance r to a center of the charge accumulation body. The generated field strength of this charge accumulation body does at least approximately not have an angular dependency, even at a space region close to the support body. In other words, the combined electric field of the charge accumulation body, which may be a charged sphere in the first illustrative example and the support body may substantially fulfill at least approximately a 1/r² dependency in proximity to the support body, reproducing a theoretically expected electric field in an environment of the charged sphere.

In a second illustrative example herein, where the charge accumulation body has the shape of a cylinder, the electric field generated by the charge accumulation body may substantially have a 1/r dependency of the electric field strength on a distance r to a center line of the charge accumulation body. The generated field strength of this charge accumulation body does at least approximately not have an angular dependency in the azimuthal direction of the cylinder, even at a space region close to the support body. In other words, the combined electric field of the charge accumulation body, which may be a charged cylinder in the second illustrative example. The support body may substantially fulfill at least approximately a 1/r dependency in proximity to the support body, reproducing a theoretically expected electric field in an environment of the charged sphere.

In accordance with some illustrative examples of the fourth illustrative embodiment of the first aspect, the support body may be rotational symmetric relative to a rotational axis and may have a first connection and a second connection. The first connection is in electrical contact with the charge accumulation body at a first side of the support body and the second connection is formed at a second side opposite the first side along the rotational axis of the support body. Accordingly, a symmetrical field distribution at the support body may be achieved.

In some special illustrative example herein, an axis of rotational symmetry of the charge accumulation body may be in alignment with the rotational axis of the support body. Accordingly, the electric field generating device may have at least one axis of rotational symmetry.

In accordance with some illustrative examples of the fourth illustrative embodiment of the first aspect in combination with the first illustrative embodiment of the first aspect, the locally varying electrical resistance may only vary along the rotational axis, while being constant in an azimuthal direction relative to the rotational axis. Accordingly, a homogeneous field distribution in the azimuthal direction of the support body may be provided.

In accordance with some illustrative examples of the fourth illustrative embodiment of the first aspect in combination with the first illustrative embodiment of the first aspect, the locally varying electrical resistance may decrease along the rotational axis from the first side to the second side. Accordingly, any disturbing influence of an electric field generated by the support body and the conductor element on the electric field of the charge accumulation body may be suppressed.

In accordance with some illustrative examples of the fourth illustrative embodiment of the first aspect, an outer surface of the support body outside the charge accumulation body, when being extended into the charge accumulation body, may have a peak at a centroid of the charge accumulation body in a side sectional view of the electric field generating device. This condition allows to implement an advantageous adequacy between a given model for the desired electric field to be generated by the electric field generating device, e.g., the desired electric field being an electric field of an ideal electrically charged sphere, and a proposed realization.

In a fifth illustrative embodiment of the first aspect, the support body may be of an annular disc shape. An according electric field generating device may be easily scaled to small sizes.

In some illustrative examples of the fifth illustrative embodiment of the first aspect, the conductor element may have a contact portion located at a first radial distance relative to a geometric center of the support body and the support body may have a connection element located at second radial distance relative to the geometric center, the first radial distance being smaller than the second radial distance such that the contact portion is partially integrated into the support body and covered by the charge accumulation body.

In some illustrative examples herein, the support body and the conductor element may each comprise a connection line radially oriented in the electric field generating device, the electric field generating device further comprising an insulating annular disc element arranged between the connection line of the support body and the connection line of the conductor element.

In some illustrative examples of the fifth illustrative embodiment of the first aspect, the contact portion may be a ring shaped element contacting the charge accumulation body.

In some illustrative examples of the fifth illustrative embodiment of the first aspect in combination with the first embodiment of the first aspect, the locally varying electrical resistance may vary between the first radial distance and the second radial distance.

In some illustrative examples of the fifth illustrative embodiment of the first aspect in combination with the first embodiment of the first aspect, the locally varying electrical resistance may decrease from the first radial distance to the second radial distance.

In some illustrative examples of the fifth illustrative embodiment of the first aspect, the charge accumulation body may be a semi-ellipsoidal body, preferably a hemispherical body.

In accordance with a sixth illustrative embodiment of the first aspect, the support body may have a varying thickness, the varying thickness being given by one of a linear function and a finite or infinite power series. Accordingly, a suitable varying thickness may be implemented by selecting an appropriate function for the thickness along the support body.

In accordance with a seventh illustrative embodiment of the first aspect, the support body may comprise regions of different materials, the regions having different electrical resistances. Accordingly, a locally varying electrical resistance may be easily realized by forming regions of different materials having different electrical resistances.

In accordance with an eighth illustrative embodiment of the first aspect, the material of the charge accumulation body may be different from at least one of the material of the support body and the material of the conductor element. The choice of a different material for the charge accumulation body may provide electrical insulation from the surrounding environment and/or protection against corrosion upon a proper choice of material.

In accordance with a ninth illustrative embodiment of the first aspect, the material of the charge accumulation body may be one of a conductive material and a dielectric material having a dielectric constant greater than 1, preferably greater than 5 or greater than 10 or greater than 100. A thin dielectric layer (i.e., a thickness of the dielectric layer is significantly smaller when compared to the dimensions of the charge accumulation body) with a low dielectric constant value provides electrical insulation and corrosion protection. A solid dielectric body, which includes a terminal to the conductor element connected to a charge return terminal of the support body, allows to shape the potential in a way similar to what a solid conductor of the same shape would provide, but without the need to transport electric charges to the external surface. In this case the charge accumulation remains at the terminal of the conductor element and the propagation of its effect is associated with the polarization of the dielectric material. If the value of its relative dielectric constant is very large compared to 1, then the equipotential surfaces within the dielectric conform to the shape of the interface. When crossing the interface, the electric field undergoes a discontinuity of its normal component, in connection with the ratio of the dielectric constant of the internal medium to the surrounding medium (having a dielectric constant of about 1). The higher this ratio is, the lower the potential difference between the terminal of the conductor element and the dielectric/surrounding medium interface. For example, the dielectric material may have a dielectric constant of greater 50, such as at least 100. In some special illustrative embodiments, the dielectric material may be a liquid, such as water having a dielectric constant of about 80, alkanes and materials based on hydrophobic molecules, or the dielectric material may be a solid material, such as titanate of Strontium (having a dielectric constant of about 300) and/or titanate of Baryum (which is used in the manufacture of the capacitors, for example).

In accordance with a tenth illustrative embodiment of the first aspect, the charge accumulation body may be one of a hollow body and a solid body. Accordingly, a charge accumulation body in form of a hollow body may be lighter, show low material consumption, and allows to be filled by liquids, whereas a charge accumulation body in form of a solid body may be composite body of a light internal material providing a desired shape and an external layer providing the electrical conduction property.

In accordance with an eleventh illustrative embodiment of the first aspect, the support body may have a thread connection with the charge accumulation body. Accordingly, a reliable but removable connection between the support body and the charge accumulation body may be provided.

In accordance with some illustrative examples of the eleventh illustrative embodiment of the first aspect, one of the support body and the charge accumulation body may have an outer thread and the other one of the support body and the charge accumulation body may have an inner thread, at least one of the outer thread and the inner thread being at least partially coated with a conductive paste, preferably a silver paste or silver-containing paste. Accordingly, an improved electrical connection may be realized by the conductive paste.

In a second aspect of the present disclosure, an electric field generating system is provided. In illustrative embodiments herein, the electric field generating system comprises at least one electric field generating device according to the first aspect and at least one power source connected to the at least one electric field generating device so as to supply the charge accumulation body with electric charges.

In accordance with a first illustrative embodiment of the second aspect, at least two electric field generating devices may be provided, the at least two electric field generating devices being divided into first and second subsets of electric field generating devices. The first subset may be coupled to one or more first poles, which are of a common first polarity, of the at least one power source, and the second subset may be coupled to one or more second poles, which are of a common second polarity, of the at least one power source, wherein the first polarity is different from the second polarity. It is possible to easily provide different configurations of field sources, such as a monopole field source when using an electric field generating system with one electric field generating device according to the first aspect being coupled to one pole of a power source, for example, the field source having a desired field distribution with suppressed or minimized perturbation of the generated field. Alternatively, a dipole field configuration may be realized when using an electric field generating system with two electric field generating devices according to the first aspect, the two electric field generating devices being coupled to poles of opposite polarity of one or more power sources. In a further alternative example, two field generating devices may be coupled to a common pole of a power source or to poles of common polarity of plural power sources such that a desired field configuration may be implemented when superimposing the electric fields generated by the field generating devices. In general, a desired electric field distribution may be realized as a superimposition of electric fields of plural electric field generating devices being arranged in subsets depending on a field polarity imposed onto the electric field generating devices and depending on an amount of voltage or current provided to the electric field generating devices. For example, a circular or elliptical field polarization of a combined electric field configuration formed from a superposition of field strengths vectors in an environment of the electric field generating devices may be obtained by appropriately superimposing two sinusoidal voltages or currents, similar to Lissajous curves as known in the art. The combined electric field configuration may be static or dynamic, depending on the electric field generating devices providing static or dynamic field sources.

In accordance with a second illustrative embodiment of the second aspect, a plurality of electric field generating devices may be provided in an arrangement according to an array having at least one row and at least one column and/or the plurality of electric field generating devices may be arranged on a substrate, preferably a printed circuit board or a flexible substrate or a rigid-flex circuit board. For example, any two mutually adjacent electric field generating devices of the plurality of electric field generating devices may be coupled to poles of opposite field polarity and a multipole arrangement may be implemented.

In accordance with a third illustrative embodiment of the second aspect in combination with an electric field generating device of the fifth embodiment of the first aspect, the electric field generating system may further comprise a flexible printed circuit board, wherein the at least one electric field generating device is mounted on the flexible printed circuit board. Accordingly, the electric field generating system may be provided the shape of a generally curved area portion.

In a third aspect of the present disclosure, an electric field detecting device is provided. In illustrative embodiments herein, the electric field detecting device comprises a pair of electrodes, and a sensor circuitry in electrical connection with the pair of electrodes, the sensor circuitry having a differential amplifier, wherein the electrodes of the pair of electrodes are coupled to respective inputs of the differential amplifier via respective connection lines, wherein the sensor circuitry comprises a cross-coupling of the connection lines upstream of the differential amplifier, the cross-coupling comprising a capacitor. Accordingly, a compact electric field detecting device with a simplified sensor circuitry may be provided.

In a fourth aspect of the present disclosure, an electric field detecting device is provided. In illustrative embodiments herein, the electric field detecting device comprises three pairs of sensing electrodes, wherein the sensing electrodes of each pair are located opposite each other along a respective connection line, the connection lines being mutually perpendicular, wherein each pair is connected to a sensor circuitry configured for measuring a scalar quantity, such as a component of an electric field, for example. Accordingly, it is possible to easily measure an electric field distribution in three-dimensional space.

In accordance with a first illustrative embodiment of the fourth aspect, the electric field detecting device may further comprise counter-electrodes, each of which being arranged in a coupling pair configuration with a respective one of the sensing electrodes, wherein the counter-electrode and the sensing electrode in each coupling pair configuration are separated from each other by an intermediate insulating body. Accordingly, a calibration of the electric field detecting device may be simplified because all sensing electrodes see a common ground signal. In practice, each two electrodes of a pair of electrodes pick up potential variations associated with a normal component of an external electric field. In the absence of counter electrodes, the sensing electrodes may see a reference potential (internal side), while in the presence of counter electrodes, the sensing electrodes may receive the copy of the potential variations associated with the external field under low impedance. Accordingly, the sensing electrodes can be considered much more isolated from the rest of the system. In some special illustrative examples herein, the counter-electrodes of each pair of sensing electrodes may be cross-connected in the sensor circuitry via an intermediate connected capacitor to the sensing electrodes such that each counter-electrode in a respective pair of sensing electrodes is electrically connected with the sensing electrode of the oppositely arranged coupling pair configuration along the respective connection line. Accordingly, a compact sensor circuitry may be provided. Another advantage may be that a numerical value of a transfer between an electric field to be measured and a voltage output of a conditioner, i.e., not a fully differential amplifier, is obtained. The value of the capacitor's capacity alone makes it possible to fix the value of this transfer, while guaranteeing that the gain of the instrumentation amplifier stage is “1”, which is a necessary condition for the maximum dynamics of this part of the instrument.

In accordance with a second illustrative embodiment of the third or fourth aspect, the electric field detecting device may further comprise a cubic body of insulating material or conductive material, wherein each pair of sensing electrodes is located on opposite sides of the cubic body. In case of the cubic body being made of an insulating material, a ground plane is provided for each of the electrode-counter-electrode pairs, while appropriate isolation of the electrodes is provided in the case of the cubic body being made of a conductive material such that any shorting of the electrodes and the cubic body is avoided. Such a detecting device may be provided in a very compact form. For example, leads of the sensing electrodes may be routed within the cubic body, the leads being lead in at a first corner, routed within the cubic body to a centroid of the cubic body, and lead out from the cubic body at a second corner of the cubic body, the second corner being located diagonally opposite the first corner.

In some special illustrative examples herein, each face of the cubic body may be covered by a curved dielectric cap so as to cover edges and corners of the cubic body. Accordingly, peaks and undesired high fields at peaks may be avoided.

In some other special illustrative examples herein, a second corner opposite the first corner may be truncated so as to form a corner face and connection lines to three sensing electrodes formed at three faces of the cubic body adjacent the corner face are routed in the cubic body. This may allow to provide the cubic body with very compact dimensions. In some special illustrative examples, the cubic body may have edges with dimensions of at least 2 mm, such as dimensions in the range from about 2 mm to about 20 mm, such as in a range from about 5 mm to about 15 mm or from about 5 mm to about 12 mm.

In a fifth aspect of the present disclosure, an electric field detection assembly is provided. In illustrative embodiments herein, the electric field detection assembly comprises the electric field detecting device of the third aspect and at least one electric field generating device of the first aspect.

In some illustrative embodiments herein, the electric field detecting device and the at least one electric field generating device may be moveable relative to each other. Alternatively, the electric field detection assembly may further comprises a base support, wherein the electric field detecting device is arranged on one face of the base support and the at least one electric field generating device may be arranged on the face of the base support adjacent the electric field detecting device. In this way, different possible implementations of an electric field detection assembly are provided.

In some illustrative embodiments of the fifth aspect, the electric field detection assembly may comprise an arrangement of at least two electric field generating devices arranged at two opposite sides of the electric field detecting device such that the electric field detecting device may be positioned at about a center of a virtual line connecting two oppositely arranged electric field generating devices.

In some illustrative embodiments of the fifth aspect, the electric field detection assembly may comprise four electric field generating devices arranged at corners of a rectangular arrangement, wherein the electric field detecting device is arranged at a geometric center of the rectangular arrangement. The electric field generating devices may provide a quadrupole arrangement generating a well-defined background field that allows to detect field perturbations against the background field with a high degree of precision.

In some illustrative embodiments of the fifth aspect, the electric field detecting device may be arranged on the face of the support such that the first corner of the cubic body of the electric field detecting device points towards the base support. This allows detecting field components along three directions by rotating the electric field detecting device relative to the support.

In some illustrative embodiments of the fifth aspect, a plurality of electric field generating devices may be arranged in an array, and wherein the electric field detection device is moveably relative to the array such that the electric field detection device passes in between two mutually adjacent electric field generating devices when moving relative to the array. Accordingly, a desired homogeneous background field distribution may be easily implemented.

In some illustrative embodiments of the fifth aspect, the electric field detection assembly may further comprise imaging rendering means configured to compute images based on signals provided by the sensor circuitry of the electric field detecting device. Accordingly, images of electric fields may be obtained by the electric field detection assembly.

After a complete reading of the present disclosure, the person skilled in the art will appreciate that the various aspects of the present disclosure may be combined in various ways. For example, an electric field generating device according to the first aspect may be employed in an electric field generating system according to the second aspect, and at least one of an electric field generating device according to the first aspect and an electric field generating system of the third aspect may be employed in an electric field detecting device according to the third aspect and/or the fourth aspect, and at least one of an electric field generating device according to the first aspect, an electric field generating system of the third aspect, and an electric field detecting device according to the third aspect and/or the fourth aspect may be employed in an electric field detecting assembly according to the fifth aspect of the present disclosure. The person skilled in the art will appreciate that any of the illustrative embodiments and examples as described above with regard to the first aspect can be combined with at least one other illustrative embodiment or example of the first aspect as described above and/or of any illustrative embodiment and/or example as described in the detailed description below. Furthermore, the person skilled in the art will appreciate that any of the illustrative embodiments and examples as described above with regard to the second aspect can be combined with at least one other illustrative embodiment or example of the second aspect as described above and/or of any illustrative embodiment and/or example as described in the detailed description below. Furthermore, the person skilled in the art will appreciate that any of the illustrative embodiments and examples as described above with regard to the third aspect can be combined with at least one other illustrative embodiment or example of the third aspect as described above and/or of any illustrative embodiment and/or example as described in the detailed description below. Furthermore, the person skilled in the art will appreciate that any of the illustrative embodiments and examples as described above with regard to the fourth aspect can be combined with at least one other illustrative embodiment or example of the fourth aspect as described above and/or of any illustrative embodiment and/or example as described in the detailed description below. Furthermore, the person skilled in the art will appreciate that any of the illustrative embodiments and examples as described above with regard to the fifth aspect can be combined with at least one other illustrative embodiment or example of the fifth aspect as described above and/or of any illustrative embodiment and/or example as described in the detailed description below.

### BRIEF DESCRIPTION OF THE DRAWINGS

The present invention will be explained in greater detail with regard to the accompanying drawings in which:

FIG. 1 schematically shows, in a sectional side view, an electric field generating device in accordance with some illustrative embodiments of the present disclosure;

FIG. 2 schematically shows, in a side view, an electric field generating device in accordance with some other illustrative embodiments of the present disclosure;

FIG. 3 schematically shows an electric field distribution of the electric field generating device of FIG. 2;

FIG. 4 schematically shows, in a diagrammatic view, a relationship between potential and distance to center of the sphere of the electric field generating device in FIG. 2;

FIG. 5 schematically shows a cross sectional view of the electric field generating device of FIG. 2;

FIG. 6 schematically shows, in a perspective view, an electric field generating device in accordance with some other illustrative embodiments of the present disclosure;

FIG. 7 schematically shows the electric field generating device of FIG. 6 in an exploded perspective view;

FIG. 8 schematically shows, in a side view, an electric field generating device in accordance with some other illustrative embodiments of the present disclosure;

FIG. 9 schematically shows an electric field generating system in accordance with some illustrative embodiments of the present disclosure;

FIG. 10 schematically shows an electric field generating system in accordance with some other illustrative embodiments of the present disclosure;

FIG. 11 schematically shows an electric field generating system in accordance with some other illustrative embodiments of the present disclosure;

FIGS. 12 and 13 show different orientations of electrical field generating devices in an electric field generating system of some illustrative embodiments of the present disclosure;

FIGS. 14a to 14e schematically show different electric field generating systems in accordance with various illustrative embodiments of the present disclosure;

FIG. 15a schematically shows an electric field detecting device in accordance with some illustrative embodiments of the present disclosure;

FIG. 15b schematically shows a front view of the cubic body in FIG. 15a;

FIG. 16 shows in a partial exploded perspective view, some details of the electric field detecting device in FIGS. 15a and 15b;

FIG. 17 schematically shows an electric field detecting device in accordance with still some other illustrative embodiments of the present disclosure;

FIG. 18 schematically shows, in a partial exploded view, some details of an electric field detecting device in accordance with some illustrative embodiments of the present disclosure;

FIG. 19 schematically shows an electric detection assembly in accordance with some illustrative embodiments of the present disclosure;

FIG. 20 schematically shows an electric field detecting assembly in accordance with some other illustrative embodiments of the present disclosure.

FIG. 21 schematically shows an electric field detecting assembly in accordance with some other illustrative embodiments of the present disclosure, employing electric field generating devices in accordance with the embodiments as described with regard to FIGS. 6 and 7;

FIG. 22 schematically shows, in a perspective bottom view, an electric field detecting assembly in accordance with some other illustrative embodiments of the present disclosure, employing electric field generating devices in accordance with the embodiments as described with regard to FIGS. 6 and 7;

FIG. 23 schematically shows the electric field detecting assembly of FIG. 22 in a perspective top view;

FIG. 24 schematically shows an electric field detecting assembly in accordance with some other illustrative embodiments of the present disclosure; and

FIG. 25 schematically shows an alternative to the electric field detecting assembly of FIG. 24.

### DETAILED DESCRIPTION

Referring to the discussion of the state of the art, it is recalled that the difficultly in measuring electric fields is that a measuring instrument influences the electric field that is to be measured, e.g., an energy supply to a probe head creates an interfering field which distorts the field to be measured and/or the mere presence of the probe materials alone (without energy supply) disturbs the electric field to be measured.

In view of this issue, the inventors recognized that a field measurement is possible when measuring a field to be measured in the presence of a well-defined background field. However, this approach poses the problem that a well-defined background field has to be generated. This is an unsolved problem, even for the simplest case of a spherical field source as it will be explained below.

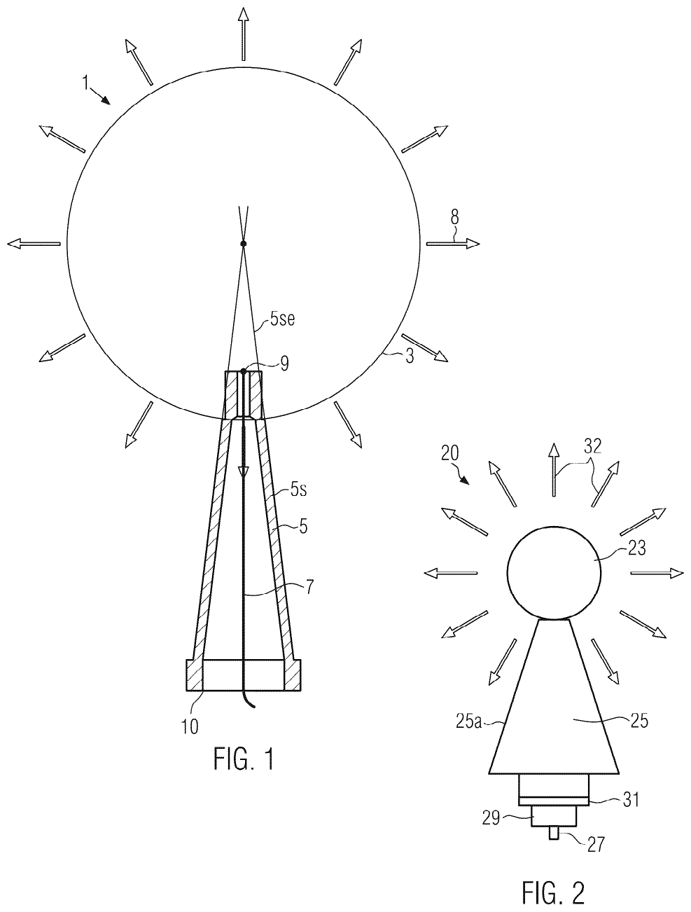

The field generating device as described below with regard to FIG. 1, represents a field source in which an electric field generated by the electric field generating device is substantially determined by a charge accumulation body of the electric field generating device of a desired shape in accordance with a desired electric potential distribution. That is, the electric field generated by the electric field generating device at least approximates or substantially corresponds to the desired electric potential distribution. In other words, any perturbing effect on an electric field generated by the charge accumulation body of the electric field generating devices caused by a support body is at least attenuated, if not avoided.

FIG. 1 shows, in a schematic side sectional view, an electric field generating device 1 having a spherical or cylindrical charge accumulation body 3 and a support body 5. Within the support body 5, a conductor element 7, e.g., a charged supply line, is routed for conducting an electrical current and supplying electrical charges to the charge accumulation body 3, e.g., when applying a given potential to the charge accumulation body 3. As shown in the illustration of FIG. 1, the support body 5 may be provided by a hollow rod or hollow sleeve body.

In some illustrative embodiments of the present disclosure, the support body 5 may be made of a dielectric material, thereby serving as a handle of the electric field generating device 1, and a provision means for the conductor element 7 to the charge accumulation body 3. For example, the support body 5 may be provided by a material suitable for 3D printing, molding or forming process techniques, such as without limitation at least one of PolyLactic Acid (PLAc), expanded thermoplastic polyurethane (EPTU), an epoxy resin (e.g., 337H), polypropylene (PP), or polyethylene (PE) and polyoxymethylene (PMO), e.g., polyoxymethylene-copolymer (POMC). However, this does not impose any limitation on the present disclosure and the support body 5 may alternatively be provided by any electrically conductive material, e.g., an electrical resistive material and/or a metal material, wherein the conductor element 7 is electrically insulated from the support body 5 by means of an insulator (not illustrated) for isolating the conductor element 7.

An electric field 8 generated by the electric field generating device 1 during operation is approximately representing the electric field of an isolated charged sphere. That is, an electric potential (not illustrated) of the electric field generated by the electric field generating device 1 during its operation has equipotential lines which are just approximately spherical.

In particular, the equipotential lines are substantially perpendicular at an outer surface 5s of the support element 5. In other words, field lines of the electric field 8 are substantially oriented in parallel to the outer surface 5s at the support element 5, where a field line is understood as representing a graphical visual aid for visualizing vector fields, consisting of a directed line which is tangent to a field vector of the generated electric field at each point along its length such that a diagram showing a representative set of neighboring field lines typically depicts a vector field as a field line diagram. In other words, the outer surface 5s of the support body 5 may be substantially parallel to the desired electric field 8 at the outer surface.

With ongoing reference to FIG. 1, the conductor element 7 is in electrical contact with the support body 5 at a contact point 9 located within the charge accumulation body 3. The contact point 9 is further in electrical contact with the charge accumulation body 3 such that an electric current may be supplied to the charge accumulation body 3. In some illustrative examples, an electric current may be supplied by the conductor element 7. In a special illustrative example herein, the support body 5 may have an electrical contact (not illustrated) provided at a base 10 of the support body 5 such that electric charges provided by the conductor element 7, may be returned from the charge accumulation body 3 via the support body 5 or vice versa.

In some illustrative embodiments, the support body 5 may have a locally varying electrical resistance which is adapted to generate the desired electric field 8. For example, the local varying electrical resistance of the support body 5 may be adopted to decrease along the support body 5 with increasing distance from the charge accumulation body 3, thereby allowing shaping of the electric field 8 close to the support body 5. In accordance with some illustrative examples, the locally varying electrical resistance may only vary along the rotational axis, while being constant in an azimuthal direction relative to the rotational axis, thereby providing the electric field 8 as a homogeneous field in the azimuthal direction of the support body 5.

In some illustrative examples herein, the support body 5 may have a varying thickness, the varying thickness being given by one of a linear function and a finite or infinite power series so as to implement the locally varying electrical resistance. For example, a suitable varying thickness may be implemented by selecting an appropriate function for the thickness along the support body in order to realize a desired locally varying electrical resistance. Additionally or alternatively, the support body 5 may comprise regions of different materials, the regions having different electrical resistances.

As shown in FIG. 1, the support body 5 may be a hollow sleeve body of a conical shape and the charge accumulation body 3 may be given by a spherical body. The support body 5 may be rotational symmetric relative to a rotational axis and an axis of rotational symmetry of the charge accumulation body 3 may be in alignment with the rotational axis of the support body 5, thereby providing a symmetrical configuration for the electric field generating device 1 having a single axis of rotation. However, this does not pose any limitation on the present disclosure and the support body 5 may be of a triangular prism shape and the charge accumulation body 3 may be of a cylindrical shape.

Still referring to FIG. 1, the outer surface 5s of the support body 5 outside the charge accumulation body 3 may be of a a geometrical configuration as illustrated in FIG. 1 via imaginary extension lines 5se representing an imaginary extension of the outer surface 5s completing the shape of the support body 5 (resembling a truncated cone shape) to a imaginary complete cone shape having an imaginary peak (illustrated in FIG. 1 as an intersection point of the imaginary lines 5se). The imaginary peak is located at a centroid of the charge accumulation body 3.

In accordance with some illustrative embodiments, the material of the charge accumulation body 3 may be different from at least one of the material of the support body 5 and the material of the conductor element 7. The choice of a different material for the charge accumulation body 3 may provide electrical insulation from the surrounding environment and/or protection against corrosion upon a proper choice of material. For example, the material of the charge accumulation body 3 may be one of a conductive material and a dielectric material having a dielectric constant greater than 1, preferably greater than 5 or greater than 10 or greater than 100.

For example, the charge accumulation body 3 may be coated with a thin dielectric layer (not illustrated), where a thickness of the dielectric layer (not illustrated) is significantly smaller when compared to the dimensions of the charge accumulation body 3 with a low dielectric constant value.

In some illustrative examples, the charge accumulation body 3 may be a solid dielectric body, which includes a terminal (not illustrated) to the conductor element 7 connected to a charge return terminal (not illustrated) of the support body 5. Alternatively, the charge accumulation body 3 may be a hollow body filled with air or some other gaseous medium, or a liquid, such as as water having a dielectric constant of about 80, alkanes and materials based on hydrophobic molecules, or it may be filled with a solid material, such as a dielectric material formed of titanate of Strontium (having a dielectric constant of about 300) and/or titanate of Baryum (which is used in the manufacture of the capacitors, for example).

With ongoing reference to FIG. 1, the support body 5 may have a thread connection (not illustrated) with the charge accumulation body 3. For example, one of the support body 5 and the charge accumulation body 3 may have an outer thread (not illustrated) and the other one of the support body 5 and the charge accumulation body 3 may have an inner thread (not illustrated). In some special illustrative but non-limiting example, at least one of the outer thread (not illustrated) and the inner thread (not illustrated) may be at least partially coated with a conductive paste, preferably a silver paste or silver-containing paste.

With regard to FIGS. 2 to 8, electric field generating devices in accordance with various other illustrative embodiments of the present disclosure are described. The person skilled in the art will appreciate that one or more features of the embodiment as described above with regard to FIG. 1 may be employed in one or more of the embodiments as described below, and vice versa.

The field generating devices as described below with regard to FIG. 2 to 8, represent field sources in which an electric field generated by the electric field generating devices is substantially determined by a charge accumulation body of the electric field generating devices of a desired shape in accordance with a desired electric potential distribution. That is, the electric field generated by the electric field generating device at least approximates or substantially corresponds to the desired electric potential distribution. In other words, any perturbing effect on an electric field generated by the charge accumulation body of the electric field generating devices caused by a support body is at least attenuated, if not avoided.

Referring to FIG. 2, an electric field generating device 20 is schematically illustrated in a schematic side view. The electric field generating device 20 comprises a spherical or cylindrical charge accumulation body 23, a support body 25 with a contact 31, and a conductor element 27. The support body 25 is made of a material having a non-vanishing electrical resistance and/or a conductive material. For example, the support body 25 may be provided by a material suitable for 3D printing, molding or forming process techniques, such as without limitation at least one of PolyLactic Acid (PLAc), expanded thermoplastic polyurethane (EPTU), an epoxy resin (e.g., 337H), polypropylene (PP), or polyethylene (PE) and polyoxymethylene (PMO), e.g., polyoxymethylene-copolymer (POMC). However, this does not impose any limitation on the present disclosure and the support body 25 may alternatively be provided by any electrically conductive material, e.g., an electrical resistive material and/or a metal material, wherein the conductor element 27 is electrically insulated from the support body 25 by means of an insulator (not illustrated) for isolating the conductor element 27.

The conductor element 27 extends through the support body 25 and, in case that the support body 25 is made of an electrically conductive material, the conductor element 27 is electrically insulated from the support body 25. For example, an insulating material 29 may be formed between the support body 25 and the conductor element 27, such as air or another dielectric material, for electrically insulating the support body 25 from the conductor element 27.

When supplying an electric charge (not illustrated) to the charge accumulation body 23, an electric field is generated in the environment of the charge accumulation body 23. FIG. 2 schematically illustrates an electric field via arrows 32 representing vectors of the electric field generated by the charge accumulation body 23. In the following, the electric field generated by the electric field generating device 20 is referred to as “the electric field 32”, As illustrated in FIG. 2, the electric field 32 corresponds to an electric field as generated by a charged sphere or charged cylinder, or at least approximates the ideal electric field outside a charged sphere or cylinder.

In accordance with some illustrative embodiments, the electric field generating device 20 may have a locally varying electrical resistance along the support body 25. For example and as illustrated in FIG. 4, a thickness of the hollow sleeve body 25 may vary along a length of the support body 25. Additionally or alternatively, a locally varying electrical resistance along the support body 25 may be obtained by an accordingly varying material composition so as to form material regions having different electrical resistance along the support body 25. For example, the local varying electrical resistance of the support body 25 may be adopted to decrease along the support body 25 with increasing distance from the charge accumulation body 23, thereby allowing shaping of the electric field 32 close to the support body 25. In accordance with some illustrative examples, the locally varying electrical resistance may only vary along the rotational axis, while being constant in an azimuthal direction relative to the rotational axis, thereby providing the electric field 32 as a homogeneous field in the azimuthal direction of the support body 25.

According to some illustrative embodiments and as illustrated in FIG. 2, the charge accumulation body 23 is of a spherical shape. For example, the charge accumulation body 23 may be coated with a thin dielectric layer (not illustrated), where a thickness of the dielectric layer (not illustrated) is significantly smaller when compared to the dimensions of the charge accumulation body 23 with a low dielectric constant value.

In some special illustrative and non-limiting examples, the charge accumulation body 23 may be a solid dielectric body, which includes a terminal (not illustrated) to the conductor element 27 connected to a charge return terminal (not illustrated) of the support body 25. Alternatively, the charge accumulation body 23 may be a hollow body filled with air or some other gaseous medium, or a liquid, such as water having a dielectric constant of about 80, alkanes and materials based on hydrophobic molecules, or it may be filled with a solid material, such as a dielectric material formed of titanate of Strontium (having a dielectric constant of about 300) and/or titanate of Baryum (which is used in the manufacture of the capacitors, for example).

With continued reference to FIG. 2, the support body 25 may be provided in form of a hollow sleeve body having a conical shape and the charge accumulation body 23 may be of a spherical shape. In some special illustrative examples herein, the support body 25 may be rotational symmetric relative to a rotational axis. An axis of rotational symmetry of the charge accumulation body 23 may be in alignment with the rotational axis of the support body 25, thereby providing a symmetrical configuration for the electric field generating device 20 having a single axis of rotation. However, this does not pose any limitation on the present disclosure and the support body 25 may be of a triangular prism shape and the charge accumulation body 23 may be of a cylindrical shape.

In accordance with some illustrative embodiments, the material of the charge accumulation body 23 may be different from at least one of the material of the support body 25 and the material of the conductor element 27. The choice of a different material for the charge accumulation body 23 may provide electrical insulation from the surrounding environment and/or protection against corrosion upon a proper choice of material. For example, the material of the charge accumulation body 23 may be one of a conductive material and a dielectric material having a dielectric constant greater than 1, preferably greater than 5 or greater than 10 or greater than 100.

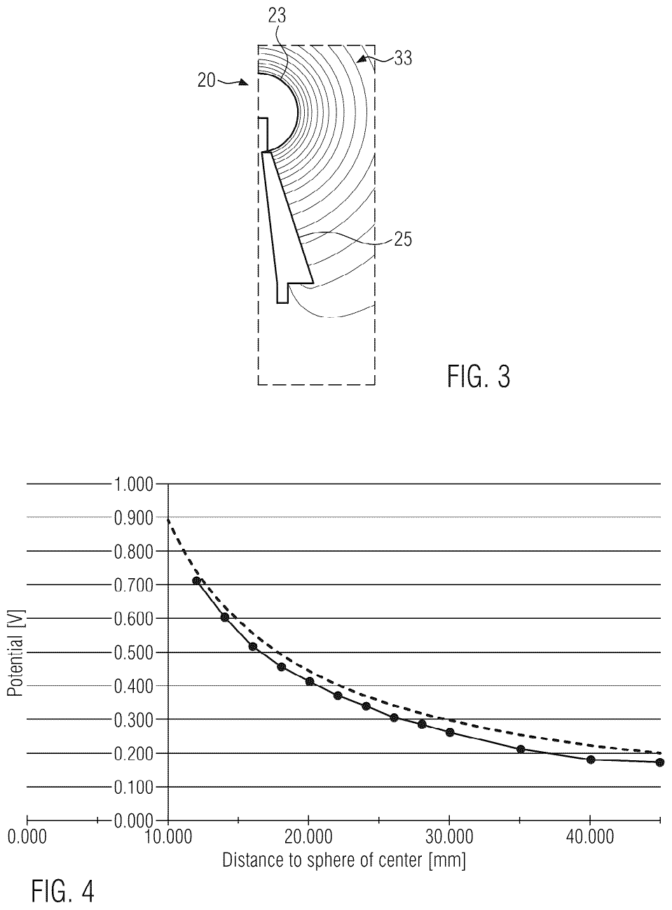

FIG. 3 schematically shows the electric field around the electric field generating device 20 in terms of an electric potential 33 visualized by equipotential lines of the illustrated electric potential field. In particular, FIG. 3 illustrates that the electric potential 33 corresponds to an electric potential as expected for a charged sphere, where the equipotential lines in the presentation of FIG. 3 are circular lines which end perpendicular on an outer surface of the support body 25. In this way, FIG. 3 demonstrates that an influence of the support body 25 and the conductor 27 on an electric field distribution of a charged sphere powered by the support body 25 and the conductor 27 is attenuated. In other words, the electric field generating device 20 generates an electrical field (see arrows 32 in FIG. 2) and an electric potential 33 which substantially complies with an electric field and electric potential of a charged sphere or charged cylinder which corresponds to an ideal field of a charged sphere or charged cylinder.

Referring to FIGS. 2 and 3, an outer surface 25a of the support body 25 is shaped such that field lines of an electric field generated by the charge accumulation body 23 substantially extend within the outer surface 25a of the support body 25. In the present disclosure, a field line is understood as representing a graphical visual aid for visualizing vector fields, consisting of a directed line which is tangent to a field vector of the generated electric field at each point along its length such that a diagram showing a representative set of neighboring field lines typically depicts a vector field as a field line diagram. Given that the arrows 32 represent electric field vectors in FIG. 2, the outer surface 25a of the support body 25 is formed such that field lines associated with some of the arrows which would be present in case that the electric field of the charge accumulation body 23 is considered without the presence of the support body 25, substantially coincide with the outer surface 25a, i.e., these field lines substantially extend within the outer surface 25a of the support body 25. In this regard, the outer surface 25a of the support body 25 may be designed in accordance with a predetermined electric field distribution to be generated by the charge accumulation body 23.

Referring to FIG. 4, a relation between a measured electric potential in dependence on a distance from the center of a charge accumulation body resembling the spherical charge accumulation body 23 as described above, is depicted. Furthermore, a broken line representing the theoretic potential of a charged sphere is depicted in FIG. 4 in comparison with the measured lines. Accordingly, FIG. 4 shows that a potential of such a spherical charge accumulation body of a electric field generating device in accordance with various embodiments of the disclosure, substantially matches with the electric potential distribution of a charged sphere.

Although the measurement and result of FIG. 4 are presented for a spherical charge accumulation body, this does not pose any limitation on the present disclosure and an according evaluation may also be applied to a cylindrical charge accumulation body in combination with a triangular prism shaped support body. In examples of a triangular prism-shaped support body, a ratio of length to radius of such a prismatic-cylindric combination may be substantially higher than unity.

In applying the results of FIG. 4 to the embodiments described above with regard to FIG. 1 to 3, the measurement of FIG. 4 shows that the electric potential generated by the electric field generating device 20, when supplying electric energy to the charge accumulation body 23, is substantially only dependent on a distance to a center of the charge accumulation body 23 without any substantial angular dependence, while an ideal relation between the potential of a charged sphere and distance to the sphere is indicated by a broken line.

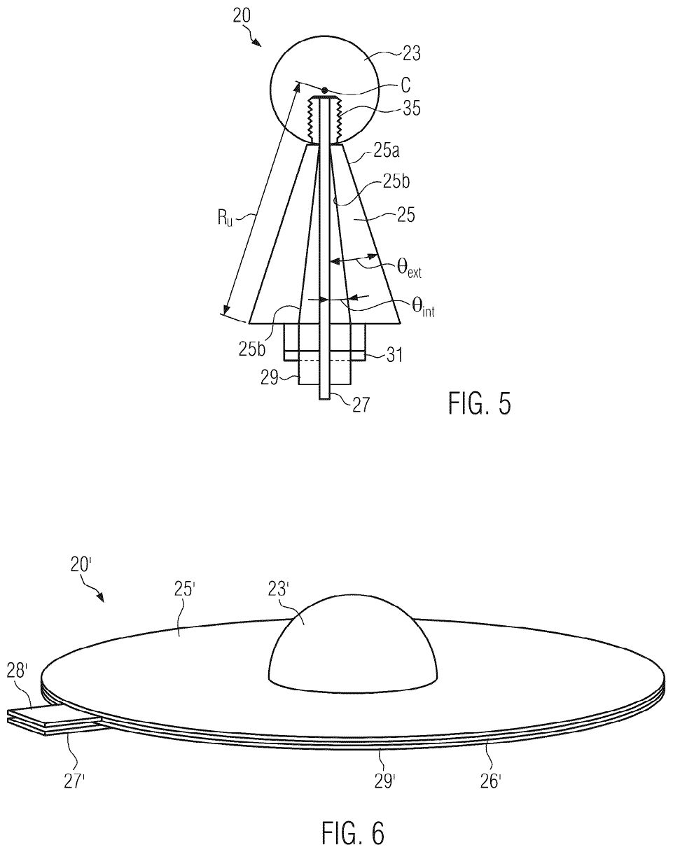

With regard to FIG. 5, some illustrative embodiments of the electric field generating device 20 of FIG. 2 to 4 are described.

In accordance with some illustrative embodiments, the support body 25 may have an electrical resistance, which is determined by the geometry of the support body 25 and its arrangement relative to the charge accumulation body 23. For example, an electrical resistance of the support body 25 may have an electrical resistance given by:

$$R = \frac{ρ}{2 π} \frac{1}{( cos {θ}_{m} - cos {θ}_{M} )} ( \frac{1}{{R}_{m}} - \frac{1}{{R}_{M}} )$$

Herein, ρ is the electrical resistivity of the material of the body 25, θ_{M} is an angle given by an angle θₑₓₜ (c.f. FIG. 5 where θₑₓₜ represents an inclination of an outer surface 25a of the support body 25) according to θ_{M}=180°−θₑₓₜ, θₘ is an angle given by an angle θᵢₙₜ (c.f. FIG. 5 where θᵢₙₜ represents an inclination of an inner surface 25b of the support body 25) according to θₘ=180°−θᵢₙₜ, Rₘ is a radius of the charge accumulation body 23, and R_{M} is a length of a center of the charge accumulation body 23 to an opposite end of the support body 25.

In some illustrative examples herein, ρ may be in a range from, about 500 Ωcm to about 2000 Ωcm, e.g., about 1000 Ωcm. The angle θₑₓₜ may be in a range up to about 10°, e.g., in a range up to about 6°, e.g. in a range from about 5° to about 6° or in a range from about 5° to about 5.5°, such as about 5.06°. The angle θᵢₙₜ may be in a range up to about 5°, e.g., in a range up to about 3°, e.g., in a range from about 2° to about 3°, such as about 2.29°. Rₘ may be in a range from about 1 cm to about 10 cm, e.g., at about 5 cm. R_{M} may be in a range from about 5 cm to about 15 cm, e.g., from about 7 cm to about 9 cm, such as about 8.5 cm.

FIG. 5 shows a schematic cross sectional view of the electrical field generating device 20 in accordance with some illustrative embodiments of the present disclosure in which the support body 25 has a varying thickness. For example, a thickness at the charge accumulation body 23 may be minimal and increases towards an opposite end of the support body 25 in proximity to the contact 31 of the support body 25. The increasing thickness of the support body 25 leads to a decreasing electrical resistance per unit length of the support body 25 along the support body 25 such that an electrical resistance per unit length of the support body 25 close to the charge accumulation body 23 is greater than an electrical resistance per unit length of the support body 25 at the opposite side of the support body 25. Accordingly, an electric current density in the support body 25 may be considered as varying such that an electric potential distribution in an environment outside the support body 25 is substantially equal to an electric potential distribution as obtained for an isolated and electrically charged sphere. In other words, the geometry and/or electrical properties of the support body 25 are adapted so as to at least attenuate any perturbing effects of the support body on an electric field generated by the charge accumulation body 23 during operation of the electrical field generating device 20.

In accordance with some illustrative embodiments, the support body 25 may be of a conical shape. In some illustrative embodiments herein, the outer surface 25a of the support body 25 outside the charge accumulation body 23 may be formed such that a peak associated to its shape (the expression “peak” is understood as indicating a tip point which is obtained when extending the lines in the illustration of FIG. 5 indicating the outer surface 25a into the charge accumulation body 23, as it is indicated by broken lines in the illustration of FIG. 5, thereby corresponding to a tip point of a geometric cone) may be located at or close to a centroid C of the charge accumulation body 23. In some special illustrative, but non-limiting examples herein and as illustrated in FIG. 5, the inner and outer surfaces 25a, 25b may be formed such that, in the illustrational view of FIG. 5, lines associated with the inner and outer surfaces 25a, 25b intersect at or close to the centroid C.

In accordance with some illustrative examples, the support body 25 may be rotation symmetrical around a rotation axis extending through the support body 25 and the conductor element 27 may be guided within the support body 25 along the rotation axis.

In some special illustrative examples, an electrical contact between the support body 25 and the conductor element 27 may be located at or in close proximity to the centroid C, e.g., located at the centroid C.

Although the above discussion of FIG. 5 is presented with regard to a spherical charge accumulation body in combination with a conical support body, this does not pose any limitation on the present disclosure and a cylindrical charge accumulation body in combination with a triangular prism shaped support body may be considered instead, leading to according results.

In accordance with some illustrative embodiments, the local varying electrical resistance along the support body 25 may be adjusted such that equipotential lines emanate from the support body 25, i.e., are substantially perpendicular to the outer surface 25a of the support body 25. Accordingly, a superposition of electrical fields generated by each of the support body 25, the conductor element 27, and the charge accumulation body 23 results in an electrical field generated by the electric field generating device 20 substantial identical with the ideal electric field of a charged sphere or cylinder.

With ongoing reference to FIG. 5, illustrative embodiments of the present disclosure are schematically illustrated in which the charge accumulation body 23 is given by a solid body, e.g., a solid body of a conductive material or a solid body of a dielectric material. Alternatively, the charge accumulation body 23 may be a solid body of dielectric material coated with a conductive material or vice versa. In still some other alternative embodiments, the charge accumulation body 23 may be a hollow body of a conductive or dielectric material or of a dielectric material coated with a conductive material or vice versa. In illustrative examples in which the charge accumulation body 23 is formed by a hollow body, liquids or gases may be contained in the hollow part. For example, such liquids or gases may have high values of their dielectric constants (e.g., pure water, alcohol, alkanes and other liquids formed by polar molecules). The according disclosure as presented in the context of FIG. 1 above, is incorporated herein by reference in its entirety.

In accordance with some illustrative embodiments herein, the support body 25 may be in a thread connection with a charge accumulation body 23. For example, and as illustrated in FIG. 5, the support body 25 may have an outer thread in mechanical engagement with an inner thread of the charge accumulation body 23. However, this does not impose any limitations on the present disclosure and the charge accumulation body 23 may have an outer thread projecting away from the charge accumulation body for mechanical engagement with an inner thread of the support body 25.

In accordance with some illustrative embodiments, the thread connection between the support body 25 and the charge accumulation body 23 may comprise a conductive paste provided on at least one of an outer thread and an inner thread of the thread connection. In accordance with some special illustrative examples herein, the conductive paste may be a silver paste or a silver containing paste which allows to increase the electrical conductivity of the thread connection.

Referring to FIG. 6, an electrical field generating device 20′ is schematically shown in a perspective view, the electric field generating device 20′ representing an alternative embodiment with respect to the electric field generating device 1 of FIG. 1 and the electric field generating device 20 of FIGS. 2 and 5. the electric field generating device 20′further comprises a support body 25′ and a conductor element 27′ being isolated from the support body 20′ by a dielectric material 29′formed in between the conductor element 27′ and the support body 25′. The isolating material 29′ may be some dielectric material having a dielectric constant greater than 1.

As shown in FIG. 6, the support body 25′ and the isolating material 29′ are each provided by a disc-shaped element, while the charge accumulation body 23′ is given by a hemispherical body. In some illustrative but non-limiting examples, a support body electrode 26′ having a contact terminal 28′ may be provided for electrically contacting the support body 25′. The support body electrode 26′ and the contact terminal 28′ are electrically insulated from the conductor element 27′ by the isolating material 29′. For example, the support body electrode 26′ may be made of a metal material, preferably of the same material and integrally formed with the contact terminal 28′, in a annular disc-shape matching at least in part with the support body 25′ and/or the isolating material 29′. Accordingly, the electric field generating device 20′ may be provided in a compact form and represents an easily scalable device. Upon scaling the electric field generating device 20′ to smaller scales, it becomes possible to generate higher field strengths and gradients when combining a plurality of accordingly scaled electric field generating devices 20′ in an electric field generating system (not illustrated).

With ongoing reference to FIG. 6, the charge accumulation body 23′ may be provided in the shape of a hemisphere. For example, the charge accumulation body 23′ may be formed of a conductive material or a dielectric material and may represent a solid body or a hollow body.

In some illustrative embodiments of the present disclosure the charge accumulation body 23′ may be a solid body, e.g., a solid body of a conductive material or a solid body of a dielectric material. Alternatively, the charge accumulation body 23′ may be a solid body of dielectric material coated with a conductive material or vice versa. In still some other alternative embodiments, the charge accumulation body 23′ may be a hollow body of a conductive or dielectric material or of a dielectric material coated with a conductive material or vice versa.

In accordance with some illustrative embodiments herein, the support body 25′ may be in a thread connection (not illustrated) with a charge accumulation body 23′. For example, the support body 25′ may have an outer thread (not illustrated) in mechanical engagement with an inner thread (not illustrated) of the charge accumulation body 23′ or vice versa. Alternatively, the charge accumulation body 23′ may be mounted to an upper planar surface of the support body 25′, e.g., at a center position of the support body 25′. For example, the charge accumulation body 23′ may be mounted by means of a gluing agent, welded or soldered to the upper planar surface of the support body 25′.

In accordance with some illustrative embodiments, the mechanical connection between the support body 25′ and the charge accumulation body 23′ may comprise a conductive paste provided between the charge accumulation body 23′ and the support body 25′. In accordance with some special illustrative examples herein, the conductive paste may be a silver paste or a silver containing paste which allows to increase the electrical conductivity of the thread connection.

In accordance with some illustrative embodiments, the electric field generating device 20′ may have a locally varying electrical resistance along the support body 25′. For example, the support body 25′ may be obtained by a varying material composition so as to form material regions having different electrical resistance along the support body 25 in order to provide a varying electrical resistance along the support body 25′. For example, the support body 25′ may have concentric disc-shaped material regions of varying electrical resistance so as to provide a locally varying resistance which only varies radially along the support body 25′.

Additionally or alternatively, the support body 25′ may have a varying thickness. For example, the thickness of the support body 25′ may be minimal at the charge accumulation body 23′ and may increases with increasing distance from a centroid of the support body 25′ towards the contact terminal 28′ of the support body 25′. The increasing thickness of the support body may also lead to a decreasing electrical resistance along the support body 25′ such that an electrical resistance close to the charge accumulation body 23′ is greater than an electrical resistance at the opposite side of the support body 25′. Accordingly, an electric current density in the support body 25′ may be considered as varying such that an electric potential distribution in an environment outside the support body 25′ is substantially equal to an electric potential distribution as obtained for an isolated and electrically charged sphere. In other words, the geometry and/or electrical properties of the support body 25′ are adapted so as to at least attenuate any perturbing effects of the support body on an electric field generated by the charge accumulation body 23′ during operation of the electrical field generating device 20′. It is noted that any change in the thickness of the support body 25′ may be compensated by a matching shape of the support body electrode such that the electric field generating device 20′ may have a constant overall thickness outside of the charge accumulation body 23′.

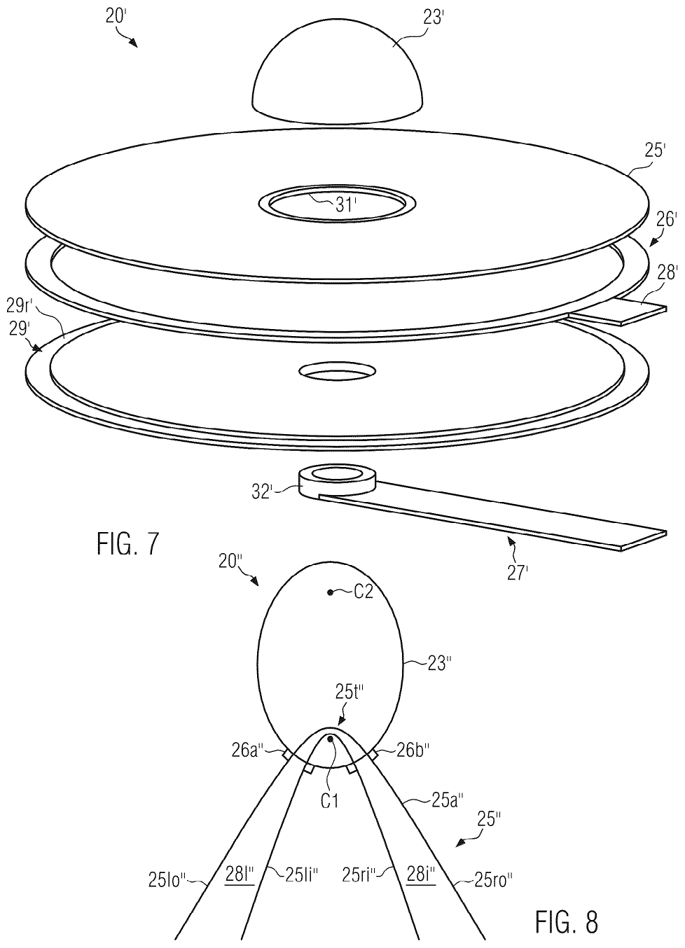

With regard to FIG. 7, the electric field generating device 20′ in accordance with some illustrative embodiments of the present disclosure is schematically illustrated in an exploded perspective view. As illustrated in FIG. 7, the support body 25′ may be of an annular disc-shape having a ring-shaped contact portion 31′ for electrically contacting a contact portion (not illustrated) of the charge accumulation body 23′. In some illustrative examples herein, the support body 25′ may be rotation symmetrical around a rotation axis extending through a centroid of the support body 25′ and the conductor element 27′ may be at least partially guided within the support body 25′ along and/or in alignment with the rotation axis. For example, the conductor element 27′ may have a cylindrical conductor portion 32′ having a center axis in alignment with the rotation axis of the support body 25′ and extending through an opening of the isolation material 29′. The isolation material 29′ may be provided by a disc-shaped dielectric body, where the opening in the isolation material 29′ is a center opening of the disc-shaped dielectric body. For example, the center opening may have a size which allows a fitting connection with the cylindrical conductor portion 32′. A center opening of the support body 25′ may be greater in size when compared to the center opening of the disc-shaped dielectric body such that a direct mechanical contact between the cylindrical conductor portion 32′ and the ring-shaped contact portion 31′ is avoided.

In accordance with some illustrative embodiments, the charge accumulation body 23′ may have the shape of a hemisphere such that an outer surface of the charge accumulation body 23′ contacts the support body 25′ with a contact angle of 90° at a mechanical contacting interface. Accordingly, an electric current flow path between the support body 25′ and the charge accumulation body 23′ may be oriented under a right angle at the mechanical and electrical interface of both bodies. Accordingly, an advantageous electric field may be generated by the electric field generating device 20′.

As illustrated in FIG. 7, the disc-shaped dielectric body providing the isolating material 29′, may have an upper surface matching with a lower surface of the support body 25′ along almost the entire lower surface of the support body 25′. A recess 29r′ may be provided in the upper surface of the disc-shaped dielectric body for accommodating the support body electrode 26′ such that a smooth and planar upper surface is provided when the support body electrode 26′ is accommodated into the recess 29r′. It is appreciated that a size of the support body electrode 26′ and a location of the recess 29r′ allow adjusting a current flow path in the support body 25′, thereby enabling adjusting a desired current density in dependence on a choice of appropriate material for the support body 25′ and in dependence on the sizes and geometries of the recess 29r′ and the support body electrode 26′.

In accordance with some illustrative examples herein, the local varying electrical resistance along the support body 25′ may be adjusted such that electrical field lines emanating from the support body 25′ may be substantially perpendicular to the outer surface 25a′ of the support body 25′. Accordingly, a superposition of electrical fields generated by each of the support body 25′, the conductor element 27′, and the charge accumulation body 23′ results in an electrical field distribution that is substantial identical with that of a charged hemisphere theoretically arranged in isolated at infinity.

Although FIGS. 6 and 7 show the conductor element 27′ and the contact terminal 28′ as extending parallel to an upper surface of the support body 25′, this does not impose any restriction and it is appreciated that at least one of the conductor element 27′ and the contact terminal 28′ may extend parallel to the rotation axis of the support body 25′.

Referring to FIG. 8, an electric field generating device 20″ in accordance with some other illustrative embodiments of the present disclosure is schematically illustrated in a side view. The electric field generating device 20″ may be similar to each of the electric field generating devices 20 and 20′ as described above with regard to FIGS. 2 to 5, while differing from these embodiments in that a charge accumulation body 23″ is of an ellipsoidal shape and a support body 25″ has a shape which is adapted to the charge accumulation body 23″ as described below. Otherwise, the electric field generating device 20″ may correspond to the electric field generating device 20 as described above in that the support body 25″ has a material composition in correspondence with the support body 25. Furthermore, the support body 25″ comprises a conductor element 27″ corresponding to the conductor element 27 and a contact 31″ corresponding to the contact 31. An insulating material 29″ may be located within the support body 25″ and between the conductor element 27″ and the support body 25″ similar to the electric field generating device 20 as described above. For example, the insulating body 29″ may be made of air or some dielectric material having a dielectric constant greater than 1.

In accordance with some illustrative embodiments, the electric field generating device 20″ may have a locally varying electrical resistance along the support body 25″. For example and as illustrated in FIG. 8, the support body 25″ may have a varying thickness. For example, the thickness of the support body 25″ may be minimal at the charge accumulation body 23″ and may increases towards an end opposite an end of the support body 25″ at which the charge accumulation body 23″ is located. The increasing thickness of the support body 23″ leads to a decreasing electrical resistance along the support body 25″ such that an electrical resistance close to the charge accumulation body 23″ is greater than an electrical resistance at the opposite side of the support body 25″. Alternatively, the locally varying electrical resistance along the support body 25″ may be obtained by a varying material composition so as to form material regions having different electrical resistance along the support body 25″ in order to provide a varying electrical resistance along the support body.

In accordance with some illustrative embodiments and as shown in FIG. 8, the support body 25″ may be of a deformed conical shape with a curved outer surface 25a″ where a shape of the outer surface 25a″ is such that field lines of an electric field generated by the charge accumulation body 23″ substantially extend within the outer surface of the support body 25″. In particular, the outer surface 25a″ of the support body 25″ is formed such that field lines associated with an electric field generated by the charge accumulation body 23″ substantially coincide with the outer surface 25a″ and, in other words, these field lines substantially extend within the outer surface 25a″ of the support body 25″. In this regard, the outer surface 25a″ of the support body 25″ may be designed in accordance with a predetermined electric field distribution to be generated by the charge accumulation body 23″.

With ongoing reference to FIG. 8, the support body 25″ may be hollow body element and the an upper portion of the support body 25″ may be accommodated into the charge accumulation body 23″ such that a tip bending portion 25t″ is located in proximity to a focus C1 of the two foci C1, C2 of the charge accumulation body 23″. A first part 251″ of the support body 25″ extends into the charge accumulation body 23″ at a terminal portion 26a″, while a second part 25r″ of the support body 25″ extends into the charge accumulation body 23″ at a terminal portion 26a″, the first and second parts 251″, 25r″ are connected by the tip bending portion 25t″.

As illustrated in FIG. 8, the outer surface 25a″ of the support body 25″ may be defined as an hyperbola confocal or substantially confocal with the charge accumulation body 23″, the vertices of the hyperbola (or the ellipse) turn around the focus C1. For example, the hollow body element of the support body 25″ may have outer surface 251o″ and 25ro″ and inner surfaces 251i″ and 25ri″ which are given by hyperbolas confocal or substantially confocal with the focus C1 of the charge accumulation body 23″ such that these hyperbolas turn around the focus C1.

In accordance with some illustrative examples, the support body 25″ may be rotation symmetrical around a rotation axis extending through the support body 25″ and the conductor element 27″ may be guided within the support body 25″ along the rotation axis.

In accordance with some illustrative embodiments, the local varying electrical resistance along the support body 25″ may be adjusted such that electrical field lines emanating from the support body 25″ may be substantially perpendicular to the outer surface 25a″ of the support body 25″. Accordingly, a superposition of electrical fields generated by each of the support body 25″, the conductor element 27″, and the charge accumulation body 23″ results in an electrical field distribution that is substantial identical with that of a charged sphere theoretically arranged in isolated at infinity.

With ongoing reference to FIG. 8, illustrative embodiments of the present disclosure are schematically illustrated in which the charge accumulation body 23″ may be given by a solid body, e.g., a solid body of a conductive material or a solid body of a dielectric material. Alternatively, the charge accumulation body 23″ may be a solid body of dielectric material coated with a conductive material or vice versa. In still some other alternative embodiments, the charge accumulation body 23″ may be a hollow body of a conductive or dielectric material or of a dielectric material coated with a conductive material or vice versa.

In accordance with some illustrative embodiments herein, the support body 25″ may be in a thread connection with a charge accumulation body 23″. For example, and as illustrated in FIG. 8, the support body 25″ may have an outer thread in mechanical engagement with an inner thread of the charge accumulation body 23″. However, this does not impose any limitations on the present disclosure and the charge accumulation body may have an outer thread projecting away from the charge accumulation body for mechanical engagement with an inner thread of the support body 25″.

In accordance with some illustrative embodiments, the thread connection between the support body 25″ and the charge accumulation body 23″ may comprise a conductive paste provided on at least one of an outer thread and an inner thread of the thread connection. In accordance with some special illustrative examples herein, the conductive paste may be a silver paste or a silver containing paste which allows to increase the electrical conductivity of the thread connection.

Although a conical support body 25″ having a charge accumulation body 23″ of an elliptical shape is described in the context of FIG. 8 in greater detail, this does not pose any limitation on the present disclosure. The support body 25″ may have a shape of a deformed triangular prism matching the sectional view of FIG. 8 when seen in a cross-sectional view and the charge accumulation body 23″ may have a shape of a deformed cylinder matching the sectional view of FIG. 8 when seen in a cross-sectional view. In an according modification, the discussion of the cross-sectional view of FIG. 8 applies accordingly.

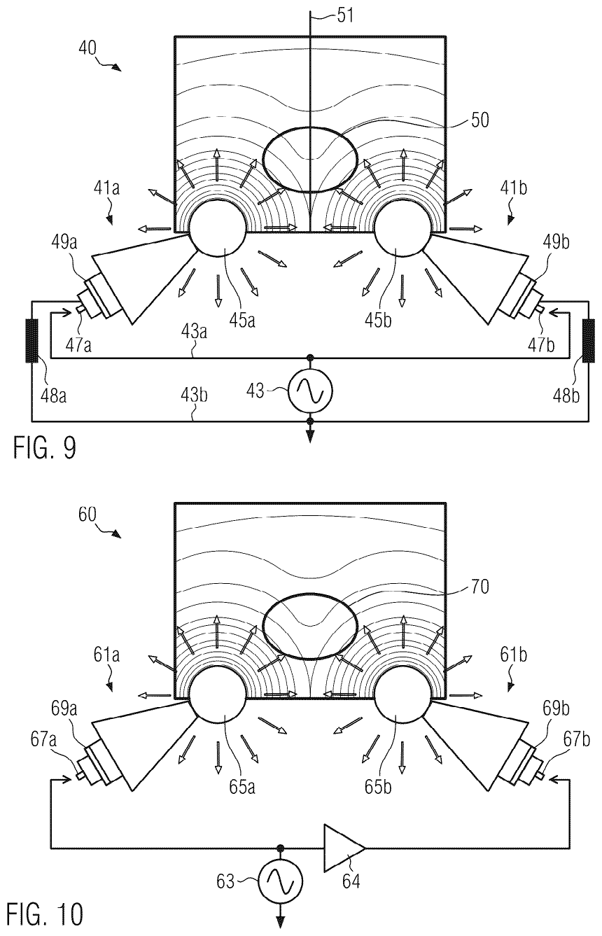

With regard to FIGS. 9 to 14, electric field generating systems in accordance with different illustrative embodiments of the present disclosure are described below.

Referring to FIG. 9, an electric field generating system 40 is schematically illustrated, the electric field generating system 40 comprising an electric field generating device 41a and an electric field generating device 41b. Each of the electric field generating devices 41a and 41b may be provided in correspondence with one of the electric field generating devices 1 and 20 to 20″ as described above in connection with FIGS. 1 to 8. Accordingly, the disclosure as described above with regard to the electric field generating devices 1 and 20 to 20″ of FIGS. 1 to 8 (although a charge accumulation body having a circular cross section and a support body having a triangular cross-section are illustrated in FIG. 9, this does not impose any limitation and the following disclosure applies accordingly to a charge accumulation body having a semi-circular cross-section with a support body having a disc-shape according to the embodiments in disclosed with regard to FIGS. 6 and 7) is incorporated in its entirety by reference at this point. That is, the electric field generating device 41a comprises a conductor element 47a extending through the support body of the electric field generating body 41a and a charge accumulation body having a contact 49a. Similarly, the electric field generating device 41b comprises a conductor element 47b extending through the support body of the electric field generating device 41b and a charge accumulation body 45b, a support body with a contact 49b. The electric field generating system 40 of FIG. 9 further comprises a power source 43 connected to each of the electric field generating devices 41a and 41b.

In accordance with some illustrative embodiments, each of the contacts 49a, 49b of the electric field generating devices 41a and 41b may be connected to a first terminal of the power source 43, e.g. a reference of the power source 43 (e.g., ground) via a connection line 43b, while each of the conductor elements 47a, 47b of the electric field generating devices 41a and 41b may be coupled to a second terminal of the power source 43 via a connection line 43a. In some illustrative embodiments of the present disclosure, the contact 49a may be coupled to the power source 43 through an appropriate resistor 48a which is connected in between the contact 49a and the power source 43 in the connection line 43b. Additionally or alternatively, the contact 49b may be coupled to the power source 43 through an appropriate resistor 48b which is connected in between the contact 49b and the power source 43 in the connection line 43b. Accordingly, an appropriate voltage drop over the resistor 48a and 48b, respectively, to the contact 47a and 47b, respectively, may be set.

Although FIG. 9 schematically shows an AC power supply as an example for the power source 43, this does not pose any limitation on the present disclosure and a DC power source may be provided instead. The power source 43 may be a current source or a voltage source. Although FIG. 9 schematically shows an AC power supply as an example for the power source 43, this does not pose any limitation on the present disclosure and a DC power source may be provided instead such that the power source 43 may be a static or dynamic power source. In some illustrative embodiments, a frequency may be in a range up to 1 MHz for sources up to 10 cm long is quite possible (where the wavelength in vacuum at 1 MHz=3 10⁸/10⁶=300 m). For example, the limiting factor of the device may be a limit for an approximation of stationary states of electromagnetism. Concretely, the length of the system along its maximum extension direction, e.g. a vertical axis in the illustration of FIG. 9, must remain very small in front of the wavelength associated with the propagation phenomenon, thereby providing an upper limit on the frequency.

The electric field generating devices 41a and 41b in the electric field generating system 40 as shown in FIG. 9, may be connected to a common terminal of the power source with a certain polarity, either + or −. Accordingly, the charge accumulation bodies 45a and 45b may be of equal polarity as indicated by the arrows in the illustration of FIG. 9. In case of the electric field generating devices 41a and 41b being connected to a common terminal of the power source 43, there is a plane 51 between the two electric field generating devices 41a and 41b at which the normal component of the electric field vanishes (i.e., the component perpendicular to the plane 51 is zero at any point of the plane 51).

In accordance with some illustrative embodiments, the electric field system 40 may realize a substantially homogeneous field region 50 with an orientation along a direction perpendicular to a direction along which a line defined by centroids of both charge accumulation bodies 45a and 45b extends.

Referring to FIG. 10, an electric field generating system 60 in accordance with some illustrative embodiments of the present disclosure is schematically shown. The electric field generating system 60 comprises an electric field generating device 61a and an electric field generating device 61b. Each of the electric field generating devices 61a and 61b may be provided in correspondence with one of the electric field generating devices 1 and 20 to 20″ as described above in connection with FIGS. 1 to 8. Accordingly, the disclosure as described above with regard to the electric field generating devices 1 and 20 to 20″ of FIGS. 1 to 8 is incorporated in its entirety by reference at this point. Although a charge accumulation body having a circular cross section and a support body having a triangular cross-section are illustrated in FIG. 10, this does not impose any limitation. The following disclosure as described with regard to FIG. 10 equally applies to a charge accumulation body having a semi-circular cross-section with a support body having a disc-shape according to the embodiments in disclosed with regard to FIGS. 6 and 7 without substantive changes.

In illustrative embodiments herein, the electric field generating device 61a comprises a charge accumulation body having a contact 69a and a conductor element 67a extending through the support body of the electric field generating body 61a. Similarly, the electric field generating device 61b comprises a charge accumulation body 65b, a support body with a contact 69b and a conductor element 67b extending through the support body of the electric field generating device 61b. The electric field generating system 60 of FIG. 10 further comprises a power source 63 connected to each of the electric field generating devices 61a and 61b. The power source 63 may be provided similar to the power source 43 as described above, the disclosure of which is incorporated in its entirety by reference. Although FIG. 10 schematically shows an AC power supply as an example for the power source 63, this does not pose any limitation on the present disclosure and a DC power source may be provided instead. The power source 63 may be a current source or a voltage source.

In accordance with some illustrative embodiments, one of the contact elements 67a, 67b of the electric field generating devices 61a and 61b may be connected to a first terminal of the power source 63, the contacts 69a, 69b of the electric field generating devices 61a and 61b may be coupled to a second terminal of the power source 63, e.g. a reference of the power source 63 (e.g., ground), and the other one of the contact elements 67a, 67b of the electric field generating devices 61a and 61b may be connected to the first terminal of the power source 63 via a polarity switching element 64. Although not illustrated in FIG. 10, the contact elements 69a, 69b may be coupled to the second terminal via one or more resistors (not illustrated) in accordance with the resistors 48a, 48b of FIG. 9 and as described in the context of FIG. 9 in this regard, the disclosure of which is incorporated at this point by reference in its entirety.

The electric field generating devices 61a and 61b in the electric field generating system 60 as shown in FIG. 10, are connected to a terminals with opposite polarity, + and −. Accordingly, the charge accumulation bodies 65a and 65b are of opposite polarity as indicated by the arrows in the illustration of FIG. 10. In the electric field system 60, it is possible to realize a substantially homogeneous field region 70 with an orientation along a direction parallel to a direction along which a line defined by centroids of both charge accumulation bodies 65a and 65b extends.

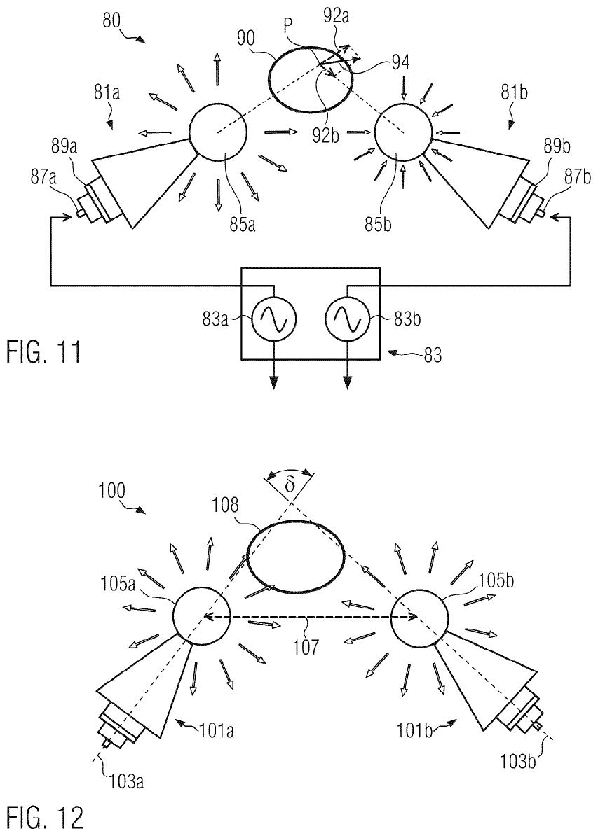

Referring to FIG. 11, an electric field generating system 80 in accordance with some illustrative embodiments of the present disclosure is schematically shown. The electric field generating system 80 comprises an electric field generating device 81a and an electric field generating device 81b. Each of the electric field generating devices 81a and 81b may be provided in correspondence with one of the electric field generating devices 1 and 20 to 20″ as described above in connection with FIGS. 1 to 8. Accordingly, the disclosure as described above with regard to the electric field generating devices 1 and 20 to 20″ of FIGS. 1 to 8 is incorporated in its entirety by reference at this point. Although a charge accumulation body having a circular cross section and a support body having a triangular cross-section are illustrated in FIG. 11, this does not impose any limitation. The following disclosure as described with regard to FIG. 11 equally applies to a charge accumulation body having a semi-circular cross-section with a support body having a disc-shape according to the embodiments in disclosed with regard to FIGS. 6 and 7 without substantive changes.

In illustrative embodiments herein, the electric field generating device 81a comprises a charge accumulation body having a contact 89a and a conductor element 87a extending through the support body of the electric field generating body 81a. Similarly, the electric field generating device 81b comprises a charge accumulation body 85b, a support body with a contact 89b and a conductor element 87b extending through the support body of the electric field generating device 81b. The electric field generating system 80 of FIG. 11 further comprises a power source 83 connected to each of the electric field generating devices 81a and 81b. The power source 83 may be constituted by a plurality of power sources, such as a power source 83a and a power source 83b, each of which corresponding to a power source as described above with regard to the power source 43 or the power source 63, the disclosures of which being incorporated in their entirety by reference.

In accordance with some illustrative embodiments, each one of the contact elements 87a, 87b of the electric field generating devices 81a and 81b may be connected to a respective first terminal of a corresponding one of the power sources 83a, 83b. For example and as illustrated in FIG. 11, the contact element 87a of the electric field generating device 81a may be connected to a respective first terminal representing a pole of a first polarity of the power source 83a and the contact 87b of the electric field generating device 81b may be connected to a respective first terminal representing a pole of a second polarity of the power source 83b, wherein the first and second polarities are of equal or opposite polarities. The contacts 89a, 89b may be connected to a reference of the power source 83, e.g., a reference of each of the power sources 83a, 83b. Although not illustrated in FIG. 11, the contact elements 89a, 89b may be coupled to the second terminal via one or more resistors (not illustrated) in accordance with the resistors 48a, 48b of FIG. 9 and as described in the context of FIG. 9 in this regard, the disclosure of which is incorporated at this point by reference in its entirety.

The electric field generating devices 81a and 81b in the electric field generating system 80 as shown in FIG. 11, are connected to terminals with opposite polarity, + and −. Accordingly, the charge accumulation bodies 85a and 85b are of opposite polarity as indicated by the arrows in the illustration of FIG. 11. An electric field at a point P in a region 90 is given by a superposition of an electric field component 92a generated by the charge accumulation body 85a and an electric field component 92b generated by the charge accumulation body 85b at the point P, resulting in the composite electric field component 94 which is substantially directed along a direction parallel to a direction along which a line defined by centroids of both charge accumulation bodies 85a and 85b extends. In case of a dynamic power source acting as the power source 83, a dynamically varying field configuration may be implemented. For example, an electric field configuration with an elliptic field polarization may be realized, such as a circular field polarization as a special example of an elliptic field polarization, by appropriately implemented power sources 83a and 83b. In some special illustrative example herein, the power sources 83a and 83b may be dynamic power sources which provide electric power with a sinusoidal time dependence and having a predetermined phase shift relative to each other and a predetermined relation between power amplitudes of the power sources 83a and 83b. In this way, any desired electric field configuration with predetermined field polarization may be obtained.

Although the embodiments as described with regard to FIG. 11 are illustrated and disclosed with regard to applying an opposite polarity to the charge accumulation bodies 85a and 85b, this does not pose any limitation on the present disclosure and a common polarity may be applied to the charge accumulation bodies 85a and 85b, instead. In this case, electric field components generated by the charge accumulation bodies 85a and 85b superimpose to a composite electric field component which is substantially perpendicular to the electric field component 94 in FIG. 11.

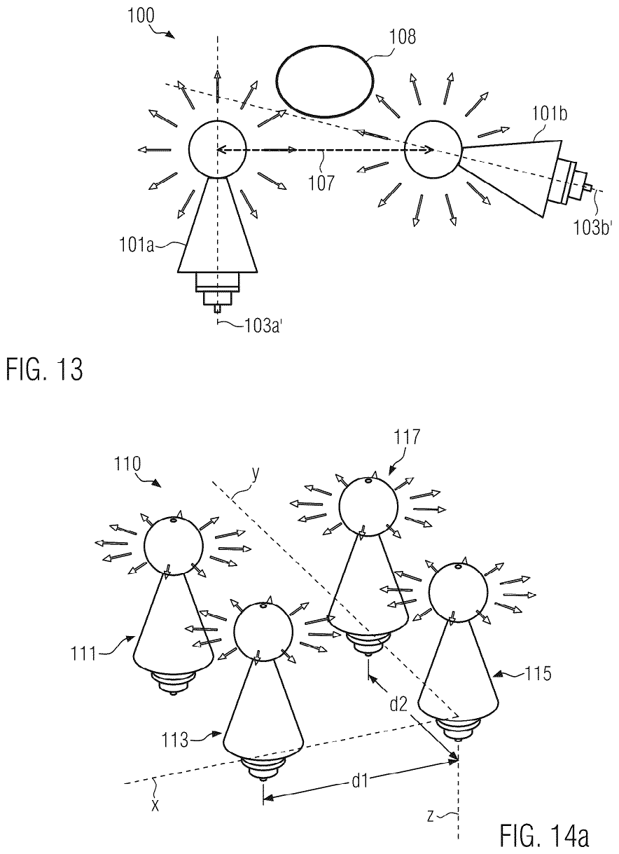

Referring to FIGS. 12 and 13, some illustrative embodiments of an electric field generating system 100 is schematically shown. The electric field generating system 100 may correspond to the electric field generating system 40 as described with regard to FIG. 9, that is, each electric field generating device 101a and 101b of the electric field generating system 100 may comprise a support body with a contact and a conductor element connected to a charge accumulation body of the respective electric field generating device 101a and 101b. The electric field generating devices 101a and 101b may be connected to a common pole of a power source or, alternatively, to poles of plural power sources being of equal plurality.

However, this does not pose any limitation on the present disclosure and the electric field generating system 100 may correspond to the electric field generating system 60 as described with regard to FIG. 10 or the electric field generating system 80 as described with regard to FIG. 11 without affecting the conclusion of the description of FIG. 12 below.

FIG. 12 shows a particular orientation of the electric field generating device 101a with respect to the electric field generating device 101b, that is, the charge accumulation bodies 105a and 105b are separated by a specific distance 107 and longitudinal axes 103a and 103b extending through the electric field generating devices 101a and 101b, are oriented to each other with a specific angle δ. A field region 108a, which may be located within a triangle formed by the longitudinal axis 103a and the longitudinal axis 103b and the separating distance 107, may be a substantially homogenous field region as described above with regard to FIG. 9 to 11.

Due to the homogeneity of the electric field generating devices 101a and 101b, the field distribution in the field region 108a does not depend on a particular orientation of the field generating devices 101a and 101b. That is, as shown in FIG. 13, a different alignment and orientation of the longitudinal axes 103a and 103b to each other, upon maintaining the distance 107, a field region 108b corresponding to a spatial location of field region 108a in FIG. 12 shows substantially the same field distribution.

Accordingly, due to the homogeneous field distribution generated by the electric field generating devices 101a and 101b, a field distribution at a given spatial location does not depend on an orientation of a longitudinal axis of the electric field generating devices.

Although electric field generating systems as described with regard to FIGS. 9 to 13 show electric field generating systems with two electric field generating devices, this does not pose any limitation on the preset disclosure and the person skilled in the art will appreciate that only one electric field generating device may be provided instead of two field generating devices.

With regard to FIGS. 9 to 13, the person skilled in the art will appreciate that the electric field generating system shown in these figures realize a dipole arrangement in case that the electric field generating devices are coupled to pole terminals of the one or more power sources having opposite polarity. In case that a single field generating device is present in the electric field generating system, a monopole configuration may be realized.

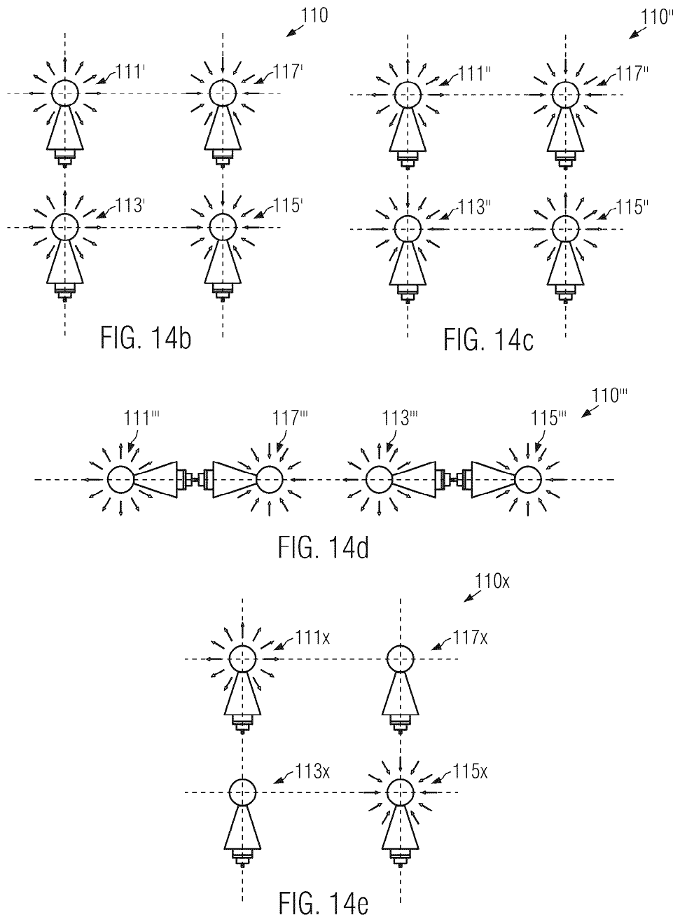

However, this does not pose any limitation on the present disclosure and any multipole arrangement may be realized by an electric field generating system having at least two electric field generating devices. For example, FIG. 14a schematically shows a configuration of an electric field generating system 110 being formed by four electric field generating devices 111, 113, 115, and 117, e.g., of equal polarity, may be arranged in a rectangular grid pattern, although this does not pose any limitation to the present disclosure and an irregular pattern may be implemented instead. For example, a longitudinal axis of each of the electric field generating devices 111, 113, 115, and 117, may be aligned along a set axis of an XY set coordinate system as schematically indicated in FIG. 14a. The electric field detecting device 113 and the electric field detecting device 115 may be arranged along a line X representing an X coordinate line in a Cartesian XYZ system at a distance d1. The electric field detecting device 117 and the electric field detecting device 115 may be arranged along a line Y representing an Y coordinate line in a Cartesian XYZ system at a distance d2. The electric field detecting device 111 and the electric field detecting device 117 may be arranged along a line in parallel to the X line at a spacing corresponding to the distance d1. The electric field detecting device 111 and the electric field detecting device 113 may be arranged along a line in parallel to the Y line at a spacing corresponding to the distance d2. In some special illustrative example, the spacing d1 may be about equal to the spacing d2 and/or the number of electric field detecting devices may be greater than four.

Although the illustration in FIG. 14a schematically shows that all the electric field generating devices 111 to 117 are coupled to at least one pole terminal (not illustrated) of at least one power source (not illustrated) with common polarity. This does not pose any limitation on the present disclosure and any other configuration may be implemented by appropriately connecting the electric field generating devices 111 to 117 with pole terminals (not illustrated) of one or more power sources with a desired field polarity pattern. For example, although FIG. 14a shows the electric field generating devices 111 to 117 as field sources, this does not pose any limitation on the present disclosure and the electric field generating devices 111 to 117 may be implemented as field sinks instead.

Referring to FIG. 14b, an electric field generating system 110′ is schematically shown, wherein electric field generating devices 111′ to 117′ are arranged in a predetermined scheme. For example, and as illustrated in FIG. 14b, the electric field generating devices 111′ and 113′ may be of positive polarity, while the electric field generating devices 115′ and 117′ may be of negative polarity. As indicated by broken lines in FIG. 14b, the electric field generating devices 111′ to 117′ may be arranged in a regular grid pattern, although this does not impose any limitation. The configuration as shown in FIG. 14b has field generating devices of equal polarity (111′, 113′ vs. 115′, 117′) arranged at positions along a vertical line as indicated via vertically extending broken lines. Although the electric field generating devices 111′ and 113′ may be of positive polarity, while the electric field generating devices 115′ and 117′ may be of negative polarity, this does not limit the present disclosure and the electric field generating devices 111′ and 113′ may be instead of negative polarity, while the electric field generating devices 115′ and 117′ may be of positive polarity. In non-depicted illustrative embodiments, field generating devices of equal polarity may be arranged at positions along a horizontal line as indicated via horizontally extending broken lines, e.g., field generating devices 111′ and 117′ may be of equal polarity and/or connected to a common terminal of a power source (not illustrated), while field generating devices 113′ and 115′ may be of equal polarity and/or connected to a common terminal of a power source (not illustrated).

In the various illustrative embodiments as described above with regard to FIG. 14b, it is possible to provide a substantially homogeneous field region between the electric field generating devices 111′ to 117′. The direction in the region of uniformity is in the horizontal plane, i.e. the plane including the centers of the spheres in the illustration of FIG. 14b.

In accordance with some special illustrative examples herein, the electric field generating devices 111′ and 113′ may be coupled to a common terminal of a power source (not illustrated), e.g., a static power source (not illustrated) or a dynamic power source (not illustrated) and the electric field generating devices 115′ and 117′ may be coupled to a common terminal of a power source (not illustrated), e.g., a static power source (not illustrated) or a dynamic power source (not illustrated). In the latter case of a dynamic power source (not illustrated), it is to be understood that the assignment of polarity as indicated in FIG. 14b is only showing the polarities at a certain point in time and, generally, electric field generating devices arranged next to each other along a vertical or horizontal line, may be coupled to a common terminal.

Referring to FIG. 14c, an electric field generating system 110″ is schematically shown, where electric field generating devices 111″ to 117″ are arranged in a quadrupole scheme. For example, and as illustrated in FIG. 14c, the electric field generating devices 111″ and 115″ may be of positive polarity, while the electric field generating devices 113″ and 117″ may be of negative polarity. As indicated by broken lines in FIG. 14c, the electric field generating devices 111″ to 117″ may be arranged in a regular grid pattern, although this does not impose any limitation. The quadrupole configuration of FIG. 14c has field generating devices of equal polarity arranged at diagonally opposite locations of the grid pattern. Although the electric field generating devices 111″ and 115″ may be of positive polarity, while the electric field generating devices 113″ and 117″ may be of negative polarity, this does not limit the present disclosure and the electric field generating devices 111″ and 115″ may be instead of negative polarity, while the electric field generating devices 113″ and 117″ may be of negative polarity.

In accordance with some special illustrative examples herein, the electric field generating devices 111″ and 115″ may be coupled to a common terminal of a power source (not illustrated), e.g., a static power source (not illustrated) or a dynamic power source (not illustrated), and the electric field generating devices 113″ and 117″ may be coupled to a common terminal of a power source (not illustrated), e.g., a static power source (not illustrated) or a dynamic power source (not illustrated). In the latter case of a dynamic power source (not illustrated), it is to be understood that the assignment of polarity as indicated in FIG. 14c is only showing the polarities at a certain point in time and, generally, electric field generating devices arranged next to each other along a vertical or horizontal line, may be coupled to a common terminal.

Although FIG. 14c schematically shows a quadrupole configuration, this does not pose any limitation to the present disclosure and one of the field generating devices 111″ and 115″ may have a negative polarity or, alternatively, one of the field generating devices 113″ and 117″ may have a positive polarity in case of a static charging provided to the field generating devices 111″ to 117″.

In the various illustrative embodiments as described above with regard to FIG. 14c, it is possible to provide an electric field in a horizontal plane above the electric field generating devices 111″ to 117″ with a linear, circular or generally elliptical field polarization (dynamic or static).

With regard to FIG. 14d, an electric field generating system 110′″ having a linear arrangement pattern of electric field generating devices 111′″ to 117′″ is schematically illustrated. Herein, the electric field generating devices 111′″ and 117′″ of opposite polarity are combined in a dipole configuration, while the electric field generating devices 113′″ and 115′″ of opposite polarity are also combined in a dipole configuration. In the shown example, the electric field generating devices 111′″ and 115′″ may be of positive polarity, while the electric field generating devices 113′″ and 117′″ may be of negative polarity. Alternatively, the polarities of the dipole pairs 111′″/117′″ and 113′″/115′″ may be interchanged. Furthermore, the dipole pairs 111′″/117′″ and 113′″/115′″ may be arranged such that their dipole axes are aligned along a common line as indicated by a broken line in the illustration of FIG. 14d.

In accordance with some special illustrative examples herein, the electric field generating devices 111′″ and 115′″ may be coupled to a common terminal of a power source (not illustrated), e.g., a static power source (not illustrated) or a dynamic power source (not illustrated) and the electric field generating devices 113′″ and 117′″ may be coupled to a common terminal of a power source (not illustrated), e.g., a static power source (not illustrated) or a dynamic power source (not illustrated). In the latter case of a dynamic power source (not illustrated), it is to be understood that the assignment of polarity as indicated in FIG. 14d is only showing the polarities at a certain point in time and, generally, electric field generating devices arranged next to each other along a vertical or horizontal line, may be coupled to a common terminal.

Referring to FIG. 14e, an electric field generating system 110x is schematically shown, where electric field generating devices 111x to 117x are arranged in a dipolar scheme. For example, and as illustrated in FIG. 14e, the electric field generating devices 111x and 115x may act as field source and field sink, respectively. That is, the electric field generating devices 111x and 115x may be of opposite polarity. The electric field generating devices 113x and 117x may be deactivated and may not be employed as field sources. For example, the electric field generating device 111x may be a field source (i.e., may be of positive polarity) and the electric field generating device 115x may be a field sink (i.e., may be of negative polarity), while the electric field generating devices 113x and 117x are not operated. This does not impose any limitation and the electric field generating device 115x may be a field source (i.e., may be of positive polarity) and the electric field generating device 111x may be a field sink (i.e., may be of negative polarity), while the electric field generating devices 113x and 117x are not operated, or the electric field generating devices 113x and 117x may act as field source and field sink, respectively, while the electric field generating devices 111x and 115x are not operated.

As indicated by broken lines in FIG. 14e, the electric field generating devices 111x to 117x may be arranged in a regular grid pattern, although this does not impose any limitation. The dipolar configuration of FIG. 14e has two field generating devices (here, in the illustrative and not limiting illustration in FIG. 14e, the electric field generating devices 111x and 115x) of opposite polarity arranged in a first diagonally opposite arrangement of the grid pattern, while two field generating devices (here, in the illustrative and not limiting illustration in FIG. 14e, the electric field generating devices 111x and 115x), which are not operated, are arranged in a second diagonally opposite arrangement of the grid pattern askew the first diagonal arrangement.

In accordance with some special illustrative examples herein, the electric field generating devices 111x and 115x may be coupled to a common terminal of a power source (not illustrated), e.g., a static power source (not illustrated) or a dynamic power source (not illustrated), and the electric field generating devices 113x and 117x may be coupled to a common terminal of a power source (not illustrated) in switched off condition, e.g., a static power source (not illustrated) or a dynamic power source (not illustrated) in the switched off condition, or the electric field generating devices 113x and 117x may not be coupled to any power source at all. In the latter case of a dynamic power source (not illustrated), it is to be understood that the assignment of polarity as indicated in FIG. 14e is only showing the polarities at a certain point in time and, generally, electric field generating devices arranged next to each other along a vertical or horizontal line, may be coupled to a common terminal.

Although FIG. 14e schematically shows a dipolar configuration, this does not pose any limitation to the present disclosure and the field generating devices 111″ and 115″ may of equal polarity.

Although FIGS. 14a to 14d schematically show electric field generating systems with four electric field generating devices, this does not pose any limitation on the present disclosure and any number greater four electric field generating devices may be arranged in the regular or irregular grid pattern. In general, the electric field generating systems as described above allow provision of versatile predictable field distributions.

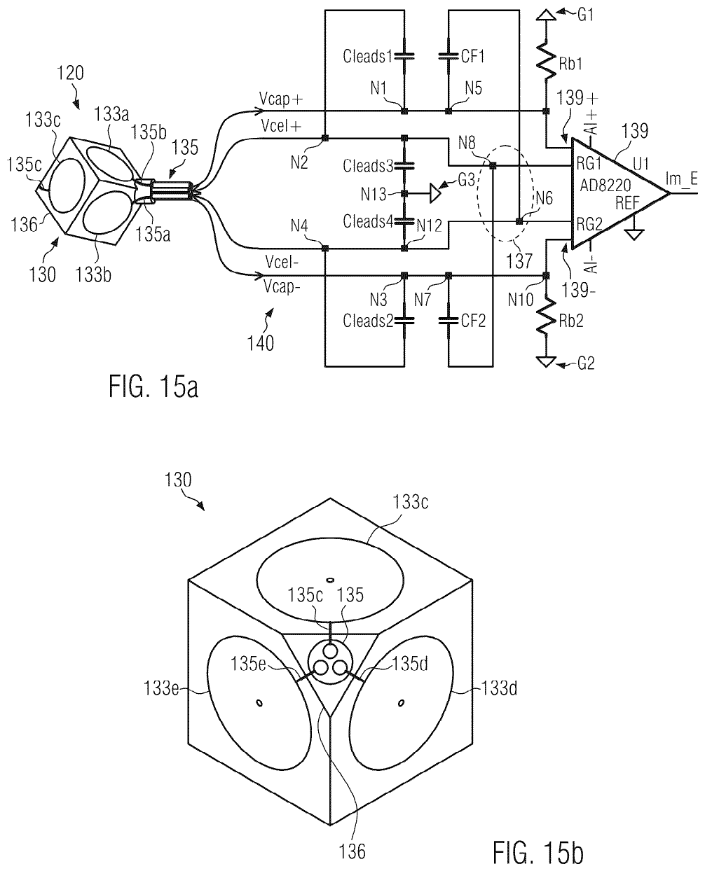

Referring to FIG. 15a, an electric field detecting device 120 is schematically illustrated, the electric field detecting device 120 having three pairs of sensing electrodes, wherein, the sensing electrodes of each pair are located opposite each other along a respective connection line, wherein the connection lines are mutually perpendicular.

With regard to the illustration in FIG. 15a, a pair of sensing electrodes is given by a sensing electrode 133a together with an oppositely arranged sensing electrode (not illustrated in FIG. 15a), another pair of sensing electrodes being given by sensing electrodes 133b together with an oppositely arranged sensing electrode (not illustrated in FIG. 15a) and a sensing electrode 133c together with an oppositely arranged sensing electrode (not illustrated in FIG. 15a).

In some illustrative embodiments and as shown in FIG. 15a, the sensing electrodes 133a to 133c may be provided on the outer surfaces of a cubic body 130 made of an insulating material. The cubic body 130 functions as a field detecting element as will be described in greater detail below.

Leads 135 of the sensing electrodes 133a to 133c are routed within the cubic body 130 to a centroid of the cubic body and lead out from the cubic body at a corner of the cubic body. The leads 135 of the sensing electrodes 133a to 133c are connected to a respective sensor circuitry 140, that is, the sensing electrodes of a pair of sensing electrodes are coupled to a respective sensor circuitry 140. In particular, the illustration in FIG. 15a shows leads 135 of sensing electrodes of a pair of sensing electrodes being lead out of the cubic body 130 at the corner of the cubic body 130 and coupled to lines Vcap+ and Vcap− of the sensor circuitry 140. These lines are coupled to + and − inputs of a differential amplifier 139.

Referring to FIGS. 15a and 15b, the cubic body 130 is cut at two opposing corners, i.e., a truncated or cut corner 136 opposite a cut corner at which the leads 135 are supplied to the cubic body 130. Some of the leads 135, that is leads 135a and 135b are routed at the side of the leads 135 to the respective sensing electrodes 133a and 133b. A third sensing electrode adjacent the leads 135 is not visible in the illustration of FIG. 15a and a lead routed from the leads 135 to this third sensing electrode (not illustrated) is not shown in FIG. 15a. Further leads of the leads 135 are routed through the cubic body 130 to the oppositely arranged cut corner 136, where these leads are guided to three sensing electrodes where only sensing electrode 133c is visible in the illustration of FIG. 15a. A lead 135c is lead out at the cut corner 136 of the cubic body 130 and routed to the sensing electrode 135c. Similarly, two more leads for connecting to two sensing electrodes which are not visible in the illustration of FIG. 15a, are guided out from the cut corner to these two sensing electrodes (not illustrated) for electrically connecting to these sensing electrodes (not illustrated).

Referring to FIG. 15b, a front view of the cubic body 130 along a direction perpendicular to the cut corner 136 is schematically illustrated, showing the sensing electrode 133c of shown in FIG. 15a together with two adjacent sensing electrodes 133d and 133e located adjacent the cut corner 136. Furthermore, the leads 135 being routed through the cubic body 130 to the cut corner 136, is schematically illustrated, showing leads 135c, 135d, and 135e. As shown in FIG. 15b, the lead 135c is electrically connected to the sensing electrode 133c, the lead 135d is electrically connected to the sensing electrode 133d, and the lead 135e is electrically connected to the sensing electrode 133e. Accordingly, it is possible to provide a very compact cubic body 130 in which six leads may be routed for electrical connection to six sensing electrodes in a space efficient manner.

In accordance with some illustrative but non-limiting examples herein, the cubic body 130 may have edges with dimensions of at least 2 mm, such as dimensions in the range from about 2 mm to about 20 mm, such as in a range from about 5 mm to about 15 mm or from about 5 mm to about 12 mm.

In accordance with some illustrative but non-limiting examples herein, the leads 135 may represent a total of six miniature coaxial cables passing into the cubic body 130. Three of the leads 135 may pass through the cubic body 130 to a top of the cubic body 130 for connecting to three pairs of electrode-counter electrode pairs.

Furthermore, each sensing electrode may be associated with a counter electrode (not illustrated in FIG. 15a), the counter electrodes of a pair of sensing electrodes is connected to gain inputs of the differential amplifier 139, in particular, the line Vcap+ is connected via a capacitance CF to a line lead out from a counter electrode (see Vcel+ and Vcel− in FIG. 15a) associated with the oppositely arranged sensing electrode and vice versa. The counter electrodes may be brought to a potential very close to that taken by the sensing electrodes directly subjected to the external field, but the connection to the gain inputs, which are at the right potential value, is at very low impedance. Under these conditions, each counter electrode may isolate its associated capture electrode from the rest of the system of conductors integrated in the sensor. The counter electrodes provide a “guarding” structure for the sensing electrodes which allows to minimize the cross talk between the various channels of the sensing electrode pairs.

In illustrative embodiments of the present disclosure, counter electrodes are cross-coupled with oppositely arranged sensing electrodes for being coupled with a gain input of the differential amplifier 139. One sensing electrode from a pair of oppositely arranged sensing electrodes is electrically connected to one of the lines Vcap+ and Vcap-, while the other one of the pair of oppositely arranged sensing electrodes is electrically connected to the other one of the lines Vcap+ and Vcap-. Only by way of example and without limitation, the sensing electrode 133c may be connected via lead 135e to the line Vcap+, while the oppositely arranged sensing electrode 133b is connected via lead 135b to the line Vcap− (alternatively, the sensing electrode 133e may be connected to line Vcap-, while the sensing electrode 133b may be connected to the line Vcap+). Similarly, sensing electrode 133d may be connected via lead 135d to the line Vcap+, while the oppositely arranged sensing electrode 133a is connected via lead 135a to the line Vcap− (alternatively, the sensing electrode 133d may be connected to line Vcap−, while the sensing electrode 133a may be connected to the line Vcap+). Similarly, the sensing electrode 133c and its oppositely arranged sensing electrode (not illustrated in FIGS. 15a and 15b) may be accordingly connected to the lines Vcap+ and Vcap−, respectively. The line Vcap+ may be connected with + input 139+ of the amplifier 139, while the line Vcap− may be connected to—input 139− of the amplifier 139. The line Vcel+ may be connected with an input RG1 of the amplifier 139 and the line Vcel− may be connected to an input RG2 of the amplifier 139.

With ongoing reference to FIG. 15a, the person skilled in the art will appreciate that the two terminals of the integrated circuit performing the differential amplification are those where the two terminals of the gain resistor fixing the gain value of the stage are connected (e.g., by soldering). The “Vcel” type electrodes, for counter electrodes, are connected to the two terminals RG1 and RG2 of the integrated circuit that can receive RG. When the desired value of Gain is “1”, then RG tends towards an infinitely large value and, in other words, it may not be necessary to connect RG, but it may be necessary to connect the Vcel+ and Vcel− leads. In this way, a guarding structure may be realized.

In the following description, the term “downstream” is understood as denoting a sequence along a direction in which an electrical signal is transported from a sensor to the amplifier 139 such that an element A is located downstream of an element B in the sense that element A is electrically arranged between element B and the amplifier 139. Similarly, “upstream” is understood as denoting a sequence along the direction in which an electrical signal is transported from a sensor to the amplifier 139 such that the element A is located upstream of the element B when element B is electrically arranged between element A and the amplifier 139.

With ongoing reference to FIG. 15a and in accordance with some illustrative embodiments, the line Vcap+ may be electrically connected with the line Vcel+ via a capacitor Cleads1 which is interconnected between a node N1 at the line Vcap+ and a node N2 at the line Vcel+. Similarly, the line Vcap− may be electrically connected with the line Vcel− via a capacitor Cleads2 which is interconnected between a node N3 at the line Vcap− and a node N4 at the line Vcel−. Although FIG. 15a shows the interconnection between lines Vcap+ and Vcel+, and between lines Vcap− and Vcel−, respectively, this does not pose any limitation on the present disclosure and at least one of these interconnections may be considered optional. Herein, the capacitor Cleads1 and Cleads2 may be understood as representing the capacitance of a signal connection, e.g., a coaxial cable, carrying Vcap and Vel signals. An external capacitor can be added in parallel, but may be omitted in case that the guarding structure is implemented. The signal connection, e.g., coaxial cable, has an electrical resistance in parallel, of a high value. In some illustrative examples herein, a linear capacity of coaxial cables may be at about 100 pF per meter, which leads to values of Cleads1 and Cleads2 of the order of 15-20 pF.

In accordance with some illustrative embodiments, the line Vcap+ may be electrically connected with the line Vcel− via a capacitor CF1 which is interconnected between a node N5 at the line Vcap+ and a node N6 at the line Vcel−. Similarly, the line Vcap− may be electrically connected with the line Vcel+ via a capacitor CF2 which is interconnected between a node N7 at the line Vcap− and a node N8 at the line Vcel+. The nodes N6 and N8 are located in a region 137 upstream of the amplifier 139. In other words, the region 137 represents a region where line Vcap+ and Vcap−, respectively, is cross-coupled with Vcel− and Vcel+, respectively before connecting to the amplifier 139. The node N5 may be located downstream of the node N1, the node N8 may be located downstream of the node N2, the node N6 may be located downstream of the node N4, and the node N7 may be located downstream of the node N3. Accordingly, a simplified sensor circuitry 140 may be provided when compared to a known circuitry as explained in the background section above.

The above described connection allows to maximize the dynamic range of the measurement. In this regard, the person skilled in the art will appreciate that it is necessary for the gain of the amplifier to become equal to about 1, on the one hand, and the CF capacitors to ensure a negative feedback of the system (negative feedback), on the other hand. According to the theory of linear servo systems, the value of the CF capacitance allows a transfer value of the system to be fixed, as well as its bandwidth. Upon fixing the maximum value of the field to be measured, i.e., in choosing the measuring range of the instrument, the value of the transfer will be also fixed in relation to the measuring range and in relation to the accessible values of the output voltage of the amplifier, which are themselves fixed by its supply voltage, for example +/−5V, +/−12V, +/−36V, according to the technology implemented. In some special illustrative examples, values for the CF capacitor may range from a few pF to a few nF, a value conditioned by the measurement range, on the one hand, and by the values of the parameters of the influence matrix associated with the physical model of the measurement probe, on the other.

In accordance with some illustrative embodiments, the line Vcap+ may be connected to ground G1 at a node N9 via a resistor Rb1 and the line Vcap− may be connected to ground G2 at a node N10 via a resistor Rb2. The node N9 may be downstream of the node N1, preferably downstream of the node N5, while the node N10 may be downstream of the node N3, preferably downstream of node N7. The resistors Rb1 and Rb2 may provide a very low value of direct current, specified in the data sheet of the differential amplifier, to the differential amplifier such that a proper functioning of the differential amplifier may be ensured. In some illustrative examples, the values of the resistors Rb1 and Rb2 may be in a range from about 0.1 GΩ to about 50 GΩ, e.g., at about 1 GΩ. A particular value for the resistors Rb1 and Rb2 may be in practice subject to a compromise because these resistors may degrade the input impedance value of the differential amplifier for variable signals, while affecting the bandwidth value.

In accordance with some illustrative embodiments, the lines Vcel+ and Vcel− may be interconnected via at least one capacitor. For example, capacitors Cleads3 and Cleads4 may be coupled in between the lines Vcel+ and Vcel−. The capacitor Cleads3 may be connected at one side with the line Vcel+ at a node N11, while the capacitor Cleads4 may be connected at one side with the line Vcel− at a node N12. Furthermore, a node N13 may be located between the capacitors Cleads3 and Cleads4 and the node N13 may be coupled to ground G3. The node N11 may be downstream of the node N2, preferably upstream of the node N8. Similarly, the node N12 may be downstream of the node N4, preferably upstream of the node N6. The capacitors Cleads3 and Cleads4 may be realized in accordance with the capacitors Cleads1 and Cleads2, the disclosure of which is incorporated by reference in its totality and accordingly applies to Cleads3 and Cleads4.

The differential amplifier may have inputs AI+ and AI− which are inputs of the integrated circuit reserved for its bipolar power supply. Admissible values for the inputs AI+ and AI− are given in technical specifications sheet of the differential amplifier.

Although the illustrative circuitry as shown in FIG. 15a is shown and described as having a plurality of nodes N1 to N12, this does not pose any limitation on the present disclosure and the skilled person will appreciate that the illustrated and described circuitry is only a schematic circuit diagram showing a functional interrelation of functional elements without explicitly defining structural features. In particular, the illustration of the circuit diagram in FIG. 15a does provide a presentation of interconnections between circuit components in the schematic diagram which corresponds to a specific physical arrangement in a finished device. For example, any of the nodes N1 to N12 may be a connection that does not necessarily imply a connection point but may instead represent any linkage or connection between two or more lines. For example, in an illustrative example of an electric field detecting device, lines maybe realized by coaxial cables and a node may represent a connection of two or more coaxial cables.

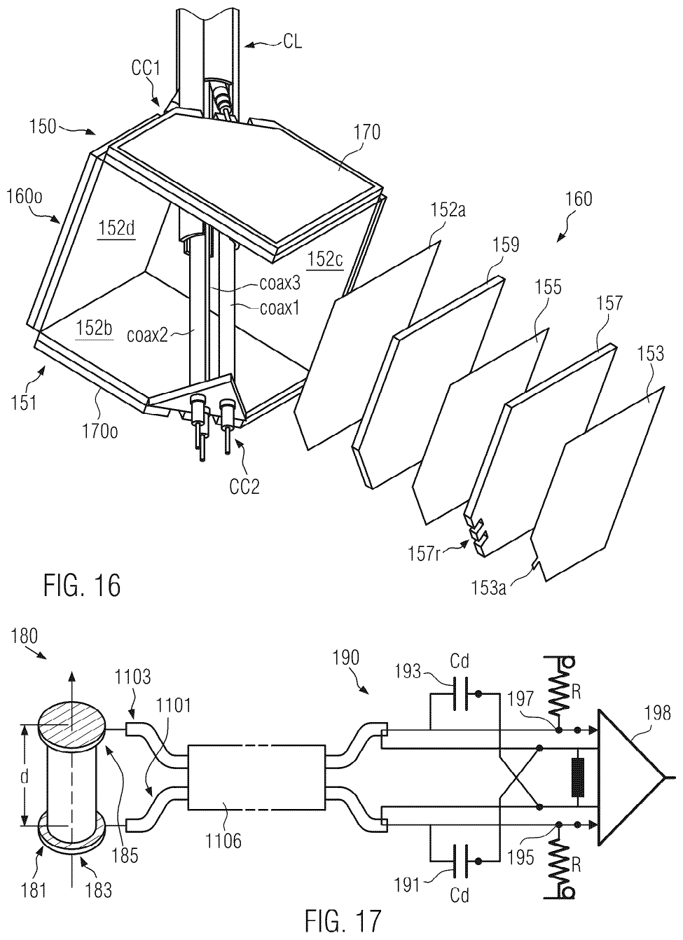

Although FIGS. 15a and 15b show sensing electrodes 133a to 133e in a circular shape when viewed in a top view, this does not impose a specific limitation on the shape of the sensing electrodes 133a to 133e and at least one of the sensing electrodes may have a polygonal shape when viewed in top view. Some special illustrative but non-limiting example will be described below with regard to FIG. 16.

Referring to FIG. 16, a field detecting element 150 is schematically illustrated in a perspective partially exploded view. The field detecting element 150 may correspond to the cubic body 120 described above and provides a cubic body 151 with a plurality of electrode pairs, thereby allowing a multi-axis field detection.

In accordance with some illustrative embodiments, FIG. 16 schematically shows a configuration of electrodes, wherein an electrode 160 of a pair of oppositely arranged electrodes 160, 160o is schematically shown in an exploded view. The electrode 160 comprises a sensing electrode 153, a counter electrode 155 and an insulator 157 arranged between the sensing electrode 153 and the counter electrode 155. This pair of the sensing electrode 153 and the counter electrode 155 of the electrode 160 is arranged on a further insulator 159 forming a sidewall of the cubic body 151. The sidewalls of the cubic body 151 formed by insulators such as insulator 159, avoid an undesired electric contact between adjacent counter electrodes. The insulator 157 has one or more recesses 157r which partially expose the counter electrode 155 when the insulator covers the counter electrode 155 such that the counter electrode 155 may be brought into electrical coupling with an electrical line as described below. For example and as shown in FIG. 16, the insulator 157 may have two recesses 157r. This does not impose any limitation and one or more than two recesses may be provided instead. The sensing electrode 153 may have a terminal 153a which is configured for coupling to an electrical line as described below. Any of the pair of oppositely electrodes 170/170o and 160/160o is provided as described with regard to the electrode 160.

As illustrated in FIG. 16, the cubic body 151 has two oppositely arranged cut corners CC1 and CC2, the cut corner CC1 representing a corner at which a plurality of connection lines CL is coupled to the cubic body 151. Six connection lines of the plurality of connection lines CL are coupled to the electrodes 170, 160o and an electrode that is not visible in the illustration of FIG. 16 and borders the cut corner CC1. These six connection lines couple to the sensing electrodes and counter electrodes of these electrodes. In some illustrative example herein, the six connection lines may be provided by three coaxial cables, each coaxial cable coupling to a pair of a sensing electrode and counter electrode of one electrode of the electrodes 170, 160o and an electrode that is not visible in the illustration of FIG. 16. For example, the counter electrode may be coupled to an outer conductor of a coaxial cable, while the inner conductor is coupled to the respective sensing electrode.

In accordance with some illustrative embodiments, internal surfaces of the cubic body 151, representing internally exposed surfaces of the insulator 159, may be covered with an electrically conductive material so as to provide reference electrodes 152a, 152b, 152c, 152d (not illustrated in the illustration of FIG. 16 are reference electrodes opposite the reference electrodes 152b and 152d) for providing internal reference electrodes. The reference electrodes 152a, 152b, 152c, 152d and the not illustrated reference electrodes opposite the reference electrodes 152b and 152d may be electrically connected such that a reference potential may be applied to the internal electrodes. For example, the internal electrodes may be electrically coupled with the plurality of connection lines CL, e.g., a reference line providing a reference potential, such that the internal electrodes may be kept on the reference potential. In some special illustrative example herein, the reference electrodes (152a, 152b, 152c, 152d together with the not illustrated reference electrodes opposite the reference electrodes 152b and 152d in FIG. 16) may be connected to a conductive tube housing the plurality of connection lines CL, that is the reference electrodes may be coupled to an electrically conductive cable sheathing which accommodates the plurality of connection lines CL.

In accordance with some special illustrative examples herein, the reference electrodes 152a, 152b, 152c, 152d may be provided as an integral cubic body which may function as an internal support for the further elements of the cubic body 151. For example, outer surfaces of this integral cubic body may be covered with the insulator 159.

Furthermore, six connection lines may be guided through the cubic body 151 to the opposite cut corner CC2 where these six connection lines may connect to the remaining three electrodes, including the electrodes 160, 170o and an electrode that is not visible in the illustration of FIG. 16 and borders the cut corner CC2. These six connection lines couple to the sensing electrodes and counter electrodes of these electrodes. In some illustrative example herein, the six connection lines may be provided by three coaxial cables coax1, coax2, and coax3, each these coaxial cables coax1, coax2, and coax3 coupling to a pair of a sensing electrode and counter electrode of one electrode of the electrodes 160, 1700 and an electrode that is not visible in the illustration of FIG. 16. For example, a counter electrode may be coupled to an outer conductor of one of the coaxial cables coax1, coax2, and coax3, while the inner conductor of this coaxial cable is coupled to the respective sensing electrode.

In some special illustrative embodiment, coaxial cable coax1 may be coupled to the counter electrode 157 via the recesses 157r and may be coupled to the sensing electrode 153 via the terminal 153a.

As partially illustrated in FIG. 16 and in accordance with some illustrative embodiments herein, the connection lines may be accommodated into a conducting tube for providing a voltage reference for the field detecting element 150 as described above. Accordingly, a compact sensor element (see sensor element 4 in FIG. 16) of an electric field detecting device may be provided.

After a complete lecture of the present disclosure, the person skilled in the art will appreciate that the cubic body 151 as described above with regard to FIG. 16 may be also employed in the context of the illustrative embodiments as described above with regard to FIGS. 15a and 15b, i.e., the embodiments as described with regard to FIGS. 15a and 15b and the embodiments as described with regard to FIG. 16 may be combined and mixed into illustrative embodiments.

Referring to FIG. 17, an electric field detecting device 180 is, in accordance with some other illustrative embodiments, schematically illustrated. The schematic illustration in FIG. 17 only shows one pair of sensing electrodes 181 given by two sensing electrodes 183 and 185 separated by distance d without one pair of counter electrodes. The electric field detecting device 180 may represent a mono-axial field detecting device or it may only represent two opposite electrodes of a pair of oppositely arranged electrodes in a multi-axial field detecting device such as one of the cubic bodies 130 and 151 as described above, the disclosure of which is incorporated by reference in its entirety at this point.

As shown in FIG. 17, leads of the sensing electrodes 183 and 185 are guided from the pair of sensing electrodes 181 as indicated by reference numerals 1101 and 1103 to a cable 1105 where all leads of the pairs 181 of sensing electrodes are collected. The cable 1105 is guided to a sensor circuitry 190 where leads of sensing electrodes are guided to a differential amplifier 198 in accordance with the description of FIGS. 15a and 16. In particular, each of the leads 1101 and 1103 may correspond to an inner conductor of a coaxial cable as described above in the context of FIG. 16.

With ongoing reference to FIG. 17, the pair 181 of sensing electrodes 183 and 185 may be circular metallic plates having a thickness less than d/2. For example, the square root of the plate's surface area may be less than d/2. Alternatively, the pair 181 may correspond to a pair of oppositely arranged sensing electrodes, such as the sensing electrode 153 in FIG. 16 and its oppositely arranged counterpart sensing electrode of the electrode 160o in FIG. 16.

In some illustrative embodiments, each electrode 183, 185 may be wired to a pin of another capacitor 191 and 193 cd and to one pin of a high nominal value resistor 195 and 197 R, in particular with 1 GΩ or more. In some illustrative examples herein, the sensor circuitry is symmetric: the capacitors and the resistor may have the same properties for the first and second electrodes. The second pins of the capacitors 187 and 189 may be connected to each other and the second pin of the resistors 195 and 197 may be connected to a reference potential of the sensor circuitry 190.

The electrodes 183 and 185 form each one main node (first and second node), in the conventional meaning of standard circuit theory and the voltages v+ and v− of the first and second node correspond to the first and second sensing means outputs like defined above. The resistors 195 and 197 are used to bias the inputs of the fully differential amplifier means 198. As shown in FIG. 17, the amplifier 198 has a differential input and a non-differential output.

FIG. 17 furthermore illustrates guarded lines 1101 and 1103 as well as a common mode guard 1105, but common guarding connections to the fully differential amplifiers are not shown for clarity.

Although FIG. 17 describes a mono-axial configuration, this does not impose any limitation and the person skilled in the art will appreciate after a complete lecture of the present disclosure that the cubic body 151 as described above with regard to FIG. 16 or the cubic body as described with regard to FIGS. 15a and 15b may be also employed in the context of the illustrative embodiments as described above with regard to FIG. 17, i.e., the embodiments as described with regard to FIG. 15a to 16 and the embodiments as described with regard to FIG. 17 may be combined and mixed into illustrative embodiments.

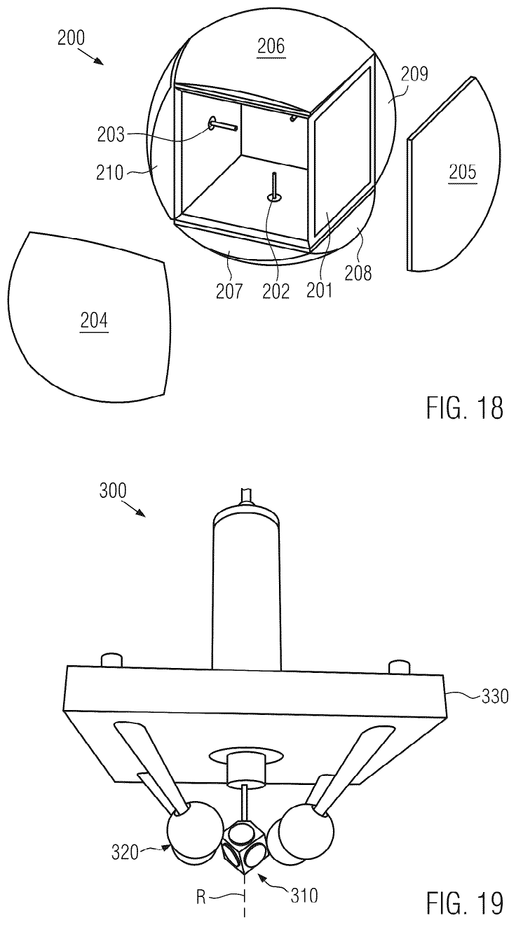

Referring to FIG. 18, a sensor element 200 of an electric field detecting device is schematically shown, the sensor element 200 comprising a cubic body 201, in accordance with a cubic body as described above with regard to any of FIG. 15a to 16 that have pairs of sensing electrodes and counter electrodes (not illustrated) which have leads routed within the cubic body 201 as indicated by leads 202 and 203 and as described above. For example, the cubic body 201 may correspond to one of the cubic bodies 130 and 151 as shown in FIGS. 15a and 16, the disclosure of which is incorporated in its entirety by reference at this point.

With ongoing reference to FIG. 18, the faces of the cubic body 201 are covered by curved dielectric cap elements 203 to 210 such that corners and edges of the cubic body 201 are totally covered by a curved dielectric cap formed by the curved dielectric cap elements 204 to 212. In this regard, an increase of an electric field at edges and corners of the cubic body is avoided.

With regard to FIG. 19, an electric field detection assembly 300 is shown. In some illustrative embodiments, the electric field detection assembly 300 comprises an electric field detecting device 310 and four electric field generating devices 320 which may be arranged at corners of a rectangular arrangement around the electric field detecting device 310, wherein the electric field detecting device 310 may be arranged at a geometric center of this rectangular arrangement.

The electric field detection device 310 may be formed in accordance with one of the electric field detection devices 120 to 180 as described above with regard to FIGS. 15a to 18 above, the disclosure of which is incorporated in its entirety by reference.

In some illustrative embodiments, the electric field detecting device 310 and the electric field generating devices 320 may be moveable relative to each other. For example, the electric field detecting device 310 may be rotatable around an axis R and/or moveable along the direction R.

With ongoing reference to FIG. 19, the electric field detection assembly 300 further comprises a base support 330 and the electric field detecting device 310 is arranged on one face of the base support 330, the electric field generating devices 320 is arranged on the face of the base support 330 adjacent the electric field detecting device 310. The electric field detecting device 310 is arranged on the face of the support 330 such that a corner of a cubic body of electric field detecting device 310 points towards the base support 330. Accordingly, it is possible to easily calibrate the electric field detection assembly 300.

Although four electric field generating devices 320 are shown in FIG. 19, this does not pose any limitation on the present disclosure and the electric field detection assembly 300 may comprise an arrangement of two electric field generating devices arranged at opposite sides of the electric field detecting device 310, three electric field generating devices arranged in a triangular arrangement around the electric field detecting device 310 or more than four electric field generating devices arranged around the electric field detecting device 310.

In accordance with some illustrative embodiments, the electric field detection assembly 300 may further comprise imaging rendering means (not illustrated) configured to compute images based on signals provided by a sensor circuitry (not illustrated, see 140 in FIG. 15a and/or 190 in FIG. 17) of the electric field detecting device 310.

In accordance with some illustrative embodiments, the electric field detection assembly 300 may be employed for imaging electric field distributions of electric field sources and/or to identify and/or characterize electric field sources. For example, deviations of electric field distributions with regard to a known background field configuration may be detected by the electric field detection assembly 300 and such deviations may be visualized by the imaging rendering means (not illustrated) so as to visualize a measured field configuration and obtain an image of an electric field distribution in an environment of the electric field detecting device 310. It is therefore possible to employ the electric field detection assembly 300 in an electric imaging application for non-destructive testing by obtaining images by eddy current.

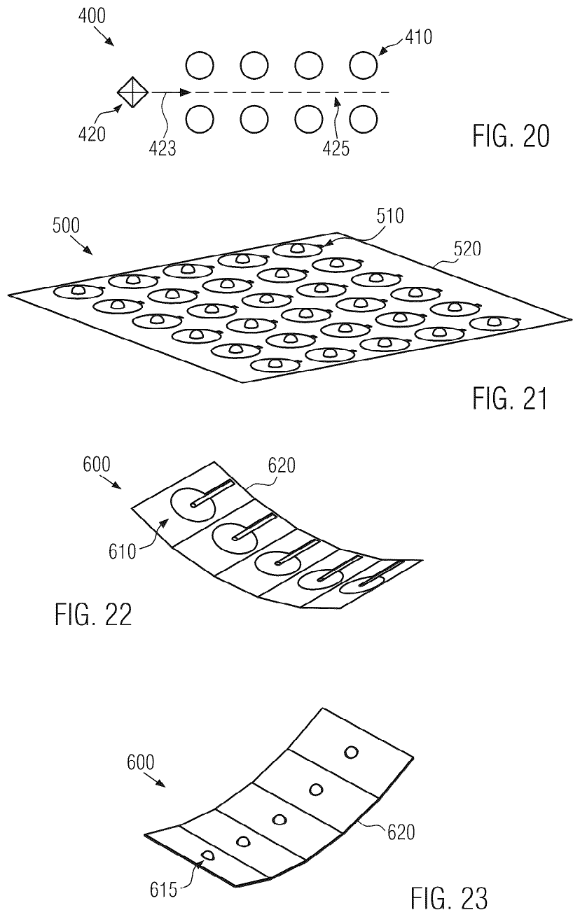

With regard to FIG. 20, an electric field detection assembly 400 is schematically shown. In some illustrative embodiments herein, the electric field detection assembly 400 comprises a plurality of electric field generating devices 410 arranged in a rectangular grid pattern on a base substrate (not illustrated). An electric field detecting device 420 may be moveable relative to each other. For example, the electric field detecting device 420 may be moveable so as to pass by the plurality of electric field generating devices 410 along a direction 423, such as a linear path 425 or a combination of linear paths oriented along perpendicular directions. Accordingly, the electric field detecting device 420 may move/be moved so as to pass in between two mutually adjacent one of the plurality of electric field generating devices 410 when moving relative to the plurality of electric field generating devices 410 along at least one direction, such as the path 425. Alternatively, the electric field generating devices 410 may move/be moved relative to the electric field detecting device 420 mounted on a base substrate (not illustrated).

In accordance with some illustrative embodiments, the electric field detection assembly 400 may further comprise imaging rendering means (not illustrated) configured to compute images based on signals provided by a sensor circuitry (not illustrated, see 140 in FIG. 15a and/or 190 in FIG. 18) of the electric field detecting device 420.

In accordance with some illustrative embodiments, the electric field detection assembly 400 may be employed for imaging electric field distributions of electric field sources and/or to identify and/or characterize electric field sources. For example, deviations of electric field distributions with regard to a known background field configuration may be detected by the electric field detection assembly 400 and such deviations may be visualized by the imaging rendering means (not illustrated) so as to visualize a measured field configuration and obtain an image of an electric field distribution in an environment of the electric field detecting device 410. It is therefore possible to employ the electric field detection assembly 400 in an electric imaging application in analogy to magnetic imaging techniques such as magnetic resonance imaging, magnetic particle imaging and the like.

With reference to FIG. 21, an electric field generating arrangement 500 is schematically illustrated in a perspective view, the field generating arrangement 500 comprising a plurality of electric field generating devices 510 formed on a substrate 510 in an arrangement pattern. The arrangement pattern may be a rectangular grid pattern, in which a first subset of two or more electric field generating devices are equidistantly positioned along a first straight line, while a second subset of two or more electric field generating devices are equidistantly positioned along a second straight line perpendicular to the first straight line. In a special example herein, a spacing of any two neighboring electric field generating devices along any of two perpendicular directions may be equal. However, this does not pose any limitation to the present disclosure and any irregular pattern may be implemented instead.

As shown in FIG. 21, the electric field generating arrangement 500 further comprises the substrate 520 on which the plurality of electric field generating devices 510 are arranged in the arrangement pattern. The substrate 520 may be a support structure for supporting the electric field generating devices 510 in a stable arrangement pattern. In some special illustrative examples herein, the substrate 520 may be a printed circuit board, thereby providing a wiring structure (not illustrated) for interconnecting the plurality of electric field generating devices 510 and/or connecting the plurality of electric field generating devices 510 with at least one power source (not illustrated), so as to supply the plurality of electric field generating devices 510 with electric energy. Such an electric field generating arrangement 500 may allow to implement a uniformly charged plane, at least to a certain degree of approximation, upon supplying currents of equal magnitude and phase to the plurality of electric field generating devices 510.

In accordance with a special illustrative example, the substrate 520 may be a flexible printed circuit board, thereby allowing to give a desired spatial shape to the electric field generating arrangement 500. For example, such an electric field generating arrangement 500 may be employed in applications in which an electric field is to be generated in accordance with a curved surface.

With ongoing reference to FIG. 21, each of the electric field generating devices 510 is illustrated similar to the electric field generating device 20′ as shown in and described with respect to FIGS. 6 and 7, the disclosure of which is incorporated by reference in its entirety. However, this does not pose any limitation on the present disclosure and at least one of the electric field generating devices 510 may be provided by one of the electric field generating devices 1, 20, and 20″ as disclosed above, possibly resulting in a hybrid configuration of different types of electric field generating devices.

In some illustrative embodiments, the electric field generating arrangement 500 may be employed in an electric field generating system as described above with regard to any of FIGS. 9 to 14, the disclosure of which is incorporated by reference in its entirety. Accordingly, upon providing an appropriate power supply to the electric field generating arrangement 500, any electric field configuration may be generated as described above with regard to any of FIGS. 9 to 14.

A possible application of the electric field generating arrangement 500 may be soil inspection of small areas, compatible with transportation means, such as robots and/or drones.

Another application may be usage of the electric field generating arrangement 500 as an electro stimulation apparatus, e.g., by placing the electric field generating arrangement 500 on a scalp of a glioblastoma patient. In such an application, the electric field generating arrangement 500 may be supplied with electric energy for inducing an electric field in a range up to 3 V/cm and frequencies in a range from about 100 kHz to about 200 kHz. In this way, intracranial electric fields can be induced, while currents directly circulating through the scalp are avoided. Accordingly, upon applying different powering modes, various field maps may be obtained. In some preferred examples herein, charge accumulation bodies of the plurality of electric field generating devices 510 may be made of a strong epsilon material or of a metal material having a dielectric coating, thereby avoiding percutaneous currents which cause inflammation and damage to a patient.

Referring to FIGS. 22 and 23, an electric field generating arrangement 600 is illustrated in a perspective view from below (see FIG. 22) and a perspective view from the top (see FIG. 23).

With reference to FIG. 22, the electric field generating arrangement 600 comprises a plurality of electric field generating devices 610 formed on a substrate 620 in a linear arrangement pattern where the plurality of electric field generating devices 610 are arranged along a straight line, preferably at an equidistant spacing. FIG. 22 shows a view from below, where support bodies of the plurality of electric field generating devices 610 are mounted to a bottom surface of the substrate 620 such that charge accumulation bodies 615 are exposed in an upper surface of the substrate 620 (see FIG. 23). As shown in FIG. 22, each electric field generating device of the plurality of electric field generating devices may be coupled to a power source, thereby allowing an individual powering of each individual electric field generating device.

Although FIGS. 22 and 23 shows a linear arrangement in which the plurality of electric field generating devices 610 are arranged along a straight line, this does not pose any limitation on the present disclosure. Instead, the arrangement pattern may be a rectangular grid pattern, in which a first subset of two or more electric field generating devices are equidistantly positioned along a first straight line, while a second subset of two or more electric field generating devices are equidistantly positioned along a second straight line perpendicular to the first straight line. In a special example herein, a spacing of any two neighboring electric field generating devices along any of two perpendicular directions may be equal. However, this does not pose any limitation to the present disclosure and any irregular pattern may be implemented instead.

In some illustrative embodiments, the substrate 620 may be provided in accordance with “flex-rigid” techniques, allowing to shape the substrate 620 in a desired curved form. Accordingly, the substrate 620 may be provided by a printed circuit board with rigid areas and flexible areas, the flexible areas having a reduced numbers of layers. For example, an illustrative substrate 620 may be a combination of polyimide and FR4, or FR4 and thin laminate. Such an electric field generating arrangement 500 may allow to implement a uniformly charged curved face, at least to a certain degree of approximation, upon supplying currents of equal magnitude and phase to the plurality of electric field generating devices 610.

With ongoing reference to FIGS. 22 and 23, each of the electric field generating devices 510 is similar to the electric field generating device 20′ as shown in and described with respect to FIGS. 6 and 7, the disclosure of which is incorporated by reference in its entirety.

In some illustrative embodiments, the electric field generating arrangement 600 may be employed in an electric field generating system as described above with regard to any of FIGS. 9 to 14, the disclosure of which is incorporated by reference in its entirety. Accordingly, upon providing an appropriate power supply to the electric field generating arrangement 600, any electric field configuration may be generated as described above with regard to any of FIGS. 9 to 14.

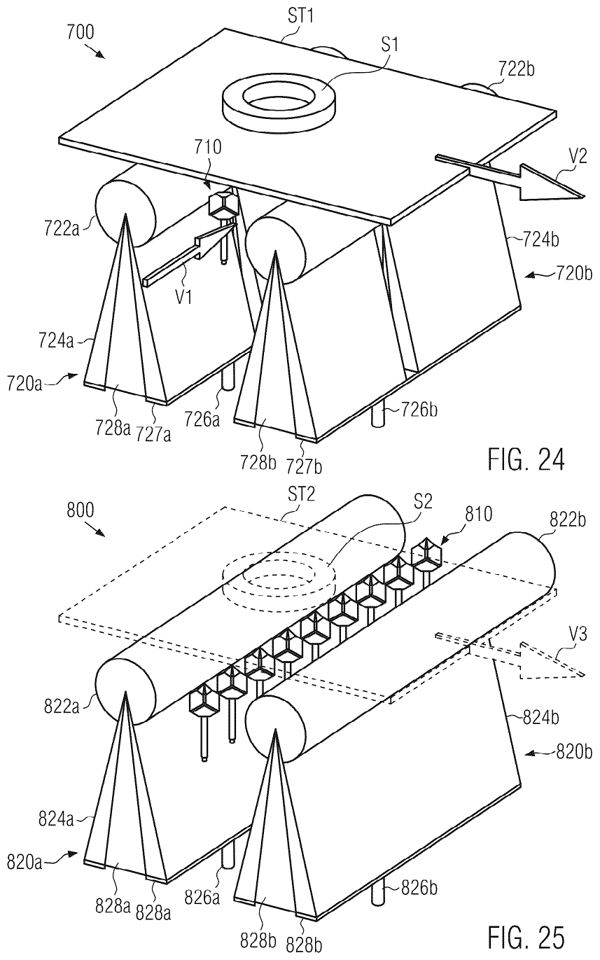

Now, reference is made to FIG. 24 showing an electric field detecting assembly 700, comprising an electric field detecting device 710 and two electric field generating devices 720a, 720b. The two electric field generating devices 720a, 720b are arranged at opposite sides of the electric field detecting device 710 and the electric field detecting device 710 is movable relative to the electric field generating devices 720a, 720b. Preferably, the electric field detecting device 710 is movable so as to move in between the electric field generating devices 720a, 720b by a movement indicated by an arrow V1. For example, the movement V1 may be in accordance with a predefined movement pattern, having at least one positive acceleration phase and at least one negative acceleration phase, optionally with at least one phase of movement with constant velocity between a positive acceleration phase and a subsequent negative acceleration phase.

The electric field detecting device 710 may correspond to an electric field detecting device as described above with regard to at least one of FIG. 15 to 18, the disclosure of which being incorporated in its entirety by reference.

As illustrated in FIG. 24, the electric field generating devices 720a and 720b each comprise a charge accumulation body 722a, 722b and a support body 724a, 724b. The illustration in FIG. 24 shows an example in which each charge accumulation body 722a, 722b is provided in form of a cylindrical body, while each support body 724a, 724b is provided in form of a triangular prism. However, this does not pose any limitation on the present disclosure and each of the electric field generating devices 720a, 720b, may be provided with one of the electric field generating devices as described above with regard to FIG. 1 to 8, the disclosure of which is incorporated in its entirety by reference.

In accordance with the illustrated embodiments, the support body 724a is electrically insulating from a conductor element 726a extending through the support body 720a, by means of an insulator 728a. A contact to the support body 724a is provided by a contact terminal 727a. Similarly, the support body 724b is electrically insulating from a conductor element 726b extending through the support body 720b, by means of an insulator 728b. A contact to the support body 724b is provided by a contact terminal 727b. An electric power signal may be supplied to the electric field generating device 720a via the conductor element 726a and the contact terminal 727a and an electric power signal may be supplied to the electric field generating device 720b via the conductor element 726b and the contact terminal 727b. Accordingly, it is possible to generate a desired field configuration by means of one or more power source (not illustrated) as described above with regard to FIG. 9 to 14.

A sample S1 may be arranged on a sample stage ST1 of a dielectric material for subjecting the sample S1 to an electric field measurement via the electric field detection assembly 700. For example, the sample S1 may be scanned by the electric field detecting device 710 when appropriately moving the sample stage ST1 relative to the electric field detection assembly 700. For example, a movement of the sample stage ST1 as indicated by arrow V2, may be perpendicular to the movement V1 and the movements V1 and V2 may be correlated in order to realize a desired scanning pattern of the electric field detecting device 710 relative to the sample S1. For example, a meander scanning may be achieved upon moving the sample stage ST1 with a constant velocity according to movement V2, while performing a back and forth oscillation movement with the electric field detecting device 710, where a velocity corresponding to movement V2 is very small compared to a maximum velocity of the movement V1. Alternatively, the movements V1 and V2 may successively stop and go such that a back and forth movement of the electric field detecting device 710 is performed during a stop of movement V2, while the movement V2 is performed during a stop of movement V1 for a short interval to displace the sample from one scanning position into a subsequent scanning position, wherein a scanning position is a position in which the movement V1 is performed.

Furthermore, the movements V1 and V2 may be determined in dependence on a desired electric field generated by the electric field generating devices 720a, 720b. For example, the electric field generating devices 720a, 720b may be supplied with a certain power signal cycle inducing a certain electric field time pattern. The movements V1 and V2 may then be performed such that a substantive change in the position of the sample relative to the electric field generating devices 720a, 720b is avoided during the electric field time pattern.

Accordingly, a nondestructive examination of sample S1 may be performed via electric fields generated by the electric field generating devices 720a and 720b being measured by the electric field detecting device 710 in presence of the sample S1.

For gauging the electric field detecting assembly 700 relative to the sample stage ST1, a measurement of the sample stage ST1 without any sample is performed.

Although FIG. 24 only shows two electric field generating devices 720a, 720b having one electric field detecting device 710 arranged there between, this does not pose any limitation on the present disclosure. Instead, more than two electric field generating devices may be present, each pair of neighboring electric field generating devices having one electric field detecting device arranged there between, Accordingly, it may be possible to subject samples of greater size in at a reduced sampling time.

Now, reference is made to FIG. 25 showing an electric field detecting assembly 800, comprising a plurality of electric field detecting devices 810 and two electric field generating devices 820a, 820b. The two electric field generating devices 820a, 820b are arranged at opposite sides of the plurality of electric field detecting devices 810. The plurality of electric field detecting devices 810 are arranged at a fixed position relative to the electric field generating devices 820a, 820b. Preferably, the plurality of electric field detecting devices 810 are arranged in a specific arrangement pattern, such as a linear pattern or a grid pattern as describe above.

Each of the plurality of electric field detecting devices 810 may correspond to an electric field detecting device as described above with regard to at least one of FIG. 15 to 18, the disclosure of which being incorporated in its entirety by reference.

As illustrated in FIG. 25, the electric field generating devices 820a and 820b each comprise a charge accumulation body 822a, 822b and a support body 824a, 824b. The illustration in FIG. 25 shows an example in which each charge accumulation body 822a, 822b is provided in form of a cylindrical body, while each support body 824a, 824b is provided in form of a triangular prism. However, this does not pose any limitation on the present disclosure and each of the electric field generating devices 820a, 820b, may be provided with one of the electric field generating devices as described above with regard to FIG. 1 to 8, the disclosure of which is incorporated in its entirety by reference.

In accordance with the illustrated embodiments, the support body 824a is electrically insulating from a conductor element 826a extending through the support body 820a, by means of an insulator 828a. A contact to the support body 824a is provided by a contact terminal 827a. Similarly, the support body 824b is electrically insulating from a conductor element 826b extending through the support body 820b, by means of an insulator 828b. A contact to the support body 824b is provided by a contact terminal 827b. An electric power signal may be supplied to the electric field generating device 820a via the conductor element 826a and the contact terminal 827a and an electric power signal may be supplied to the electric field generating device 820b via the conductor element 826b and the contact terminal 827b. Accordingly, it is possible to generate a desired field configuration by means of one or more power source (not illustrated) as described above with regard to FIG. 9 to 14.

A sample S2 may be arranged on a sample stage ST2 of a dielectric material for subjecting the sample S2 to an electric field measurement via the electric field detection assembly 800. For example, the sample S2 may be scanned by the plurality of electric field detecting devices 810 when appropriately moving the sample stage ST2 relative to the electric field detection assembly 800. For example, a movement of the sample stage ST2 as indicated by arrow V3, may be perpendicular to a direction along which at least a subset of the plurality of electric field detecting devices 810 are arranged, i.e., perpendicular to a linear arrangement of the plurality of electric field detecting devices 810.

Furthermore, the movement V3 may be determined in dependence on a desired electric field generated by the electric field generating devices 820a, 820b. For example, the electric field generating devices 820a, 820b may be supplied with a certain power signal cycle inducing a certain electric field time pattern. The movement V3 may then be performed such that a substantive change in the position of the sample relative to the electric field generating devices 820a, 820b is avoided during the electric field time pattern.

Accordingly, a nondestructive examination of sample S2 may be performed via electric fields generated by the electric field generating devices 820a and 820b being measured by the electric field detecting device 810 in presence of the sample S2.

For gauging the electric field detecting assembly 800 relative to the sample stage ST2, a measurement of the sample stage ST2 without any sample is performed.

Although FIG. 25 only shows two electric field generating devices 820a, 820b having a plurality of electric field detecting devices 810 arranged there between, this does not pose any limitation on the present disclosure. Instead, more than two electric field generating devices may be present, each pair of neighboring electric field generating devices having a plurality of electric field detecting devices arranged there between, Accordingly, it may be possible to subject samples of greater size in at a reduced sampling time.

Accordingly, a complex assembly may be avoided because only a movement means for moving the sample stage ST2 relative to the electric field detecting assembly 800 is necessary.

1. An electric field generating device, comprising:
a charge accumulation body having a shape so as to at least approximate a desired electric field around the charge accumulation body;
a support body in mechanical connection with the charge accumulation body; and
a conductor element extending through the support body and electrically contacting the support body, wherein the conductor element is electrically insulated from the support body.

2. The electric field generating device of claim 1, wherein the support body has a locally varying electrical resistance adapted to generate an electric field such that an electric field generated by the electric field generating device is substantially an electric field generated by the charge accumulation body charged with an electric charge.

3. The electric field generating device of claim 1, wherein the conductor element is in electrical contact with the support body at a contact point, the contact point being located within the charge accumulation body.

4. The electric field generating device of claim 1, wherein an outer surface of the support body is substantially parallel to the desired electric field at the outer surface.

5. The electric field generating device of claim 1, wherein the support body comprises a hollow sleeve body having one of a conical shape or a triangular prism shape.

6. The electric field generating device of claim 5, wherein the charge accumulation body comprises an ellipsoidal body having one of a spherical body, or a cylindrical body.

7. The electric field generating device of claim 5, wherein the support body is rotational symmetric with regard to a rotational axis, and wherein the support body has a first connection and a second connection, the first connection being in electrical contact with the charge accumulation body at a first side of the support body, while the second connection is formed at a second side opposite the first side along the rotational axis of the support body.

8. The electric field generating device of claim 7, wherein an axis of rotational symmetry of the charge accumulation body may be in alignment with the rotational axis of the support body.

9. The electric field generating device of claim 7, wherein the locally varying electrical resistance only varies along the rotational axis, while being constant in an azimuthal direction relative to the rotational axis.

10. The electric field generating device of claim 7, wherein the locally varying electrical resistance decreases along the rotational axis from the first side to the second side.

11. The electric field generating device of claim 5, wherein an outer surface of the support body outside the charge accumulation body, when being extended into the charge accumulation body, has a peak at a centroid of the charge accumulation body in a side sectional view of the electric field generating device.

12. The electric field generating device of one of claim 1, wherein the support body is of an annular disc shape.

13. The electric field generating device of claim 12, wherein the conductor element has a contact portion located at a first radial distance relative to a geometric center of the support body and the support body has a connection element located at second radial distance relative to the geometric center, the first radial distance being smaller than the second radial distance such that the contact portion is partially integrated into the support body and covered by the charge accumulation body.

14. The electric field generating device of claim 13, wherein the support body and the conductor element each comprise a connection line radially oriented in the electric field generating device, the electric field generating device further comprising an insulating annular disc element arranged between the connection line of the support body and the connection line of the conductor element.

15. The electric field generating device of claim 13, wherein the contact portion is a ring shaped element contacting the charge accumulation body.

16. The electric field generating device of claim 13, wherein the locally varying electrical resistance varies between the first radial distance and the second radial distance.

17. The electric field generating device of claim 1, wherein the locally varying electrical resistance decreases from the first radial distance to the second radial distance.

18. The electric field generating device of claim 12, wherein the charge accumulation body is a semi-ellipsoidal body, preferably a hemispherical body.

19. The electric field generating device of claim 1, wherein the support body has a varying thickness, the varying thickness being given by one of a linear function and a finite or infinite power series.

20. The electric field generating device of claim 1, wherein the support body comprises regions of different materials, the regions having different electrical resistances.

21. The electric field generating device of claim 1, wherein the material of the charge accumulation body is different from at least one of the material of the support body and the material of the conductor element.

22. The electric field generating device of claim 1, wherein a material of the charge accumulation body is one of a conductive material and a dielectric material having a dielectric constant greater than 1, preferably greater than 5 or greater than 10 or greater than 100.

23. The electric field generating device of claim 1, wherein the charge accumulation body is one selected from a group consisting of a hollow body and a solid body.

24. The electric field generating device of claim 1, wherein the support body has a thread connection with the charge accumulation body.

25. The electric field generating device of claim 24, wherein one of the support body and the charge accumulation body has an outer thread and the other one of the support body and the charge accumulation body has an inner thread, at least one of the outer thread and the inner thread being at least partially coated with a conductive paste, preferably a silver paste or silver-containing paste.

26. The electric field generating system, comprising at least one electric field generating device according to claim 1 and at least one power source connected to the at least one electric field generating device so as to supply the charge accumulation body with electric charges.

27. The electric field generating system of claim 26, wherein at least two electric field generating devices are provided, the at least two electric field generating devices being divided into first and second subsets of electric field generating devices, wherein the first subset is coupled to one or more first poles, which are of a common first polarity, of the at least one power source, while the second subset is coupled to one or more second poles, which are of a common second polarity, of the at least one power source, wherein the first polarity is different from the second polarity.

28. The electric field generating system of claim 27, wherein the power source is a dynamic power source.

29. The electric field generating system of claim 26, wherein a plurality of electric field generating devices is provided, the plurality of electric field generating devices being arranged in an array of at least one row and at least one column and/or wherein the plurality of electric field generating devices is arranged on a substrate, preferably a printed circuit board or a flexible substrate or a rigid-flex circuit board.

30. The electric field generating system of claim 29, wherein any two mutually adjacent electric field generating devices of the plurality of electric field generating devices are coupled to poles of opposite polarity.

31. The electric field generating system of claim 26, further comprising a flexible printed circuit board, wherein the at least one electric field generating device is mounted on the flexible printed circuit board.

32. An electric field detecting device, comprising:
a pair of electrodes,
a sensor circuitry in electrical connection with the pair of electrodes, the sensor circuitry having a differential amplifier, wherein each of the electrodes of the pair of electrodes are coupled to respective inputs of the differential amplifier via respective connection lines,
wherein the sensor circuitry comprises a cross-coupling of the connection lines upstream of the differential amplifier, the cross-coupling comprising a capacitor.

33. An electric field detecting device, comprising:
three pairs of sensing electrodes, wherein each of the sensing electrodes of each pair are located opposite each other along a respective connection line, the connection lines being mutually perpendicular, wherein each pair of sensing electrodes is connected to a sensor circuitry configured for measuring a scalar quantity.

34. The electric field detecting device of claim 33, further comprising counter-electrodes, each of which being arranged in a coupling pair configuration with a respective one of the sensing electrodes, wherein the counter-electrode and the sensing electrode in each coupling pair configuration are separated from each other by an intermediate insulating body.

35. The electric field detecting device of claim 34, wherein the counter-electrodes of each pair of sensing electrodes are cross-connected in the sensor circuitry via an intermediately connected capacitor to the sensing electrodes such that each counter-electrode in a respective pair of sensing electrodes is electrically connected with the sensing electrode of the oppositely arranged coupling pair configuration along the respective connection line.

36. The electric field detecting device of claim 32, further comprising a cubic body of insulating material, wherein each pair of sensing electrodes is located on opposite sides of the cubic body.

37. The electric field detecting device of claim 36, wherein leads of the sensing electrodes are routed within the cubic body to a centroid of the cubic body and lead out from the cubic body at a first corner of the cubic body.

38. The electric field detecting device of claim 36, wherein each face of the cubic body is covered by a curved dielectric cap so as to cover edges and corners of the cubic body.

39. The electric field detecting device of claim 36, wherein a second corner opposite the first corner is truncated so as to form a corner face and connection lines to three sensing electrodes formed at three faces of the cubic body adjacent the corner face are routed in the cubic body.

40. The electric field detection assembly, comprising: the electric field detecting device of claim 32, wherein the electric field detecting device and at least one electric field generating device are moveable relative to each other, or the electric field detection assembly further comprises a base support, wherein the electric field detecting device is arranged on one face of the base support and the at least one electric field generating device is arranged on the face of the base support adjacent the electric field detecting device.

41. The electric field detection assembly of claim 40, comprising an arrangement of at least two electric field generating devices arranged at opposite sides of the at least one electric field detecting device.

42. The electric field detection assembly of claim 40, comprising four electric field generating devices arranged at corners of a rectangular arrangement, wherein the electric field detecting device is arranged at a geometric center of the rectangular arrangement.

43. The electric field detection assembly of claim 40, wherein the electric field detecting device is arranged on the face of the support such that the first corner of the electric field detecting device points towards the base support.

44. The electric field detection assembly of claim 40, wherein a plurality of electric field generating devices is arranged in an array, and wherein the electric field detection device is moveably relative to the array such that the electric field detection device passes in between two mutually adjacent electric field generating devices when moving relative to the array.

45. The electric field detection assembly of claim 40, further comprising imaging rendering means configured to compute images based on signals provided by the sensor circuitry of the electric field detecting device.
